(19) United States
(12) Patent Application Publication
(10) Pub. No.: US 2025/0275303 A1
(43) Pub. Date: Aug. 28, 2025

(54) EPITAXIAL WAFER, METHOD FOR PREPARING THE SAME AND DISPLAY DEVICE

(71) Applicant: JADE BIRD DISPLAY (SHANGHAI) LIMITED, SHANGHAI (CN)

(72) Inventor: Wei LV, Shanghai (CN)

(21) Appl. No.: 19/063,352

(22) Filed: Feb. 26, 2025

(30) Foreign Application Priority Data
Feb. 26, 2024 (CN) 202410211782.7

(51) Int. Cl. H10H 20/825; H10H 20/01; H10H 20/812; H10H 20/813; H10H 20/815

(52) U.S. Cl. CPC H10H 20/8252; H10H 20/0137; H10H 20/812; H10H 20/813; H10H 20/815

(57) ABSTRACT

An epitaxial wafer, a method for preparing the same and a display device are provided. The epitaxial wafer includes an N-type doped layer, a functional well structure and a P-type doped structure sequentially arranged in a stacked manner. The functional well structure includes a light emitting substructure, and the light emitting substructure includes a redundant barrier layer. The redundant barrier layer is disposed between the N-type doped layer and the P-type doped structure. The redundant barrier layer has the function of blocking electrons, avoiding a high electron concentration in the functional well structure.

This application claims the benefit of priority to Chinese patent application No. 202410211782.7, filed on Feb. 26, 2024, entitled “EPITAXIAL WAFER, METHOD FOR PREPARING THE SAME AND DISPLAY DEVICE,” the entire disclosure of which is incorporated herein by reference.

### TECHNICAL FIELD

The present disclosure relates to the technical field of epitaxial structures, and more particularly to an epitaxial wafer, a method for preparing the epitaxial wafer and a display device.

### BACKGROUND

Multiple quantum well LED (MQW LED) is a special type of light-emitting diode. In an epitaxial wafer of the quantum well LED, a light emitting layer includes a quantum well structure, which has a higher radiative recombination rate of electrons and holes and a higher light emitting efficiency.

The epitaxial wafer of the quantum well LED has advantages such as high light emitting efficiency, adjustable emission light wavelength and low operating voltage. Therefore, quantum well structures are increasingly being applied in display technology to improve the performance of display devices.

However, the light emitting efficiency of the epitaxial wafer of existing quantum well LED epitaxial wafers needs to be further improved.

### SUMMARY OF THE DISCLOSURE

The problem to be solved by the present disclosure is how to further improve a light emitting efficiency of an epitaxial wafer of a quantum well LED.

An embodiment of the present disclosure provides an epitaxial wafer. The epitaxial wafer includes an N-type doped layer, a functional well structure and a P-type doped structure arranged in a stacked manner. The functional well structure is disposed between the N-type doped layer and the P-type doped structure, and the functional well structure includes a light emitting substructure and a transition substructure disposed between the light emitting substructure and the N-type doped layer.

Another embodiment of the present disclosure provides an epitaxial wafer. The epitaxial wafer includes an N-type doped layer, a functional well structure and a P-type doped structure arranged in a stacked manner. The functional well structure includes a light emitting substructure. The light emitting substructure includes a redundant barrier layer disposed between the N-type doped layer and the P-type doped structure.

Another embodiment of the present disclosure provides a display device. The display device includes an epitaxial wafer according to the present disclosure.

Another embodiment of the present disclosure provides a method for preparing an epitaxial wafer. The method includes: forming an N-type doped layer on a substrate; forming a functional well structure on the N-type doped layer, wherein the step of forming the functional well structure on the N-type doped layer includes: sequentially forming a transition substructure and a light emitting substructure on the N-type doped layer; and forming a P-type doped structure on the light emitting substructure.

Another embodiment of the present disclosure provides a method for preparing an epitaxial wafer. The method includes: forming an N-type doped layer on a substrate; forming a functional well structure on the N-type doped layer, wherein the step of forming the functional well structure on the N-type doped layer includes: forming a redundant barrier layer on the N-type doped layer; and forming a P-type doped structure on the N-type doped layer.

Compared with conventional technology, the embodiments of the present disclosure have following advantages.

According to some embodiments, the functional well structure disposed between the N-type doped layer and the P-type doped structure includes a light emitting substructure and a transition substructure disposed between the light emitting substructure and the N-type doped layer. In the light emitting substructure, the functional well structure is a multiple quantum well structure, and a barrier layer in the multiple quantum well structure has a weak blocking effect on holes, which can increase a migration distance of holes, thereby increasing the number of light emitting quantum wells and improving light emitting efficiency of the epitaxial wafer.

According to some embodiments, the light emitting substructure further includes a redundant barrier layer disposed between the multi-period light emitting layer and the P-type doped structure. The redundant barrier layer has the function of blocking electrons, avoiding a high electron concentration in the multiple quantum well structure. Electrons in the multiple quantum well structure migrate to the P-type doped structure, and have a non-radiative recombination with holes in the P-type doped structure, which affects the light emitting efficiency of the epitaxial wafer. The transition substructure is disposed between the light emitting substructure and the N-type doped layer, thus an electron concentration of the light emitting layer can be effectively controlled without an N-type current diffusion layer between the N-type doped layer and the light emitting substructure, which can improve a balance between electrons and holes in the light emitting layer, thereby effectively improving the light emitting efficiency of the epitaxial wafer. Moreover, the electron concentration in the light emitting layer can be controlled through the transition substructure without an electron blocking layer between the P-type doped layer and the light emitting substructure, which can effectively increase a migration distance of holes and effectively improve the light emitting efficiency of the epitaxial wafer.

According to some embodiments, the P-type doped structure includes a P-type layer and a multi-period doped layer. The multi-period doped layer is disposed between the P-type layer and the functional well structure. The multi-period doped layer includes a plurality of doped stack layers, and each of the plurality of doped stack layers includes a ternary doped layer and a binary doped layer. The ternary doped layer is disposed between the binary doped layer of a same doped stack layer and the functional well structure. The multi-period doped layer can increase effective hole concentration, improve hole injection efficiency, enhance a balance of electrons and holes in the light emitting substructure, lower an annealing temperature for subsequent annealing process, and effectively reduce an impact of the annealing process on potential wells in the functional well structure.

### BRIEF DESCRIPTION OF THE DRAWINGS

FIG. 1 illustrates a schematic cross-sectional view of an epitaxial wafer;

FIG. 2 illustrates a schematic cross-sectional view of an epitaxial wafer according to an embodiment of the present disclosure;

FIG. 3 illustrates a schematic cross-sectional view of a light emitting substructure of an epitaxial wafer according to an embodiment of the present disclosure;

FIG. 4 illustrates a schematic cross-sectional view of a transition substructure of an epitaxial wafer according to an embodiment of the present disclosure;

FIG. 5 illustrates a schematic cross-sectional view of a p-type doped structure of an epitaxial wafer according to an embodiment of the present disclosure;

FIG. 6 illustrates a schematic cross-sectional view of a stress adjustment structure of an epitaxial wafer according to an embodiment of the present disclosure;

FIG. 7 illustrates a schematic flowchart of a method for preparing an epitaxial wafer according to an embodiment of the present disclosure;

FIG. 8 illustrates a schematic flowchart of steps for forming a functional well structure in the method for preparing an epitaxial wafer shown in FIG. 7 according to an embodiment of the present disclosure; and

FIG. 9 illustrates a schematic flowchart of a method for preparing an epitaxial wafer according to an embodiment of the present disclosure.

### DETAILED DESCRIPTION

As mentioned in the background, the light emitting efficiency of the epitaxial wafer of existing quantum well LED epitaxial wafers needs to be further improved.

A hole concentration in MQW LEDs plays a decisive role in the brightness of an epitaxial wafer of a light-emitting diode. In group III-V (such as gallium nitride, GaN) substrate, a hole mobility (about 10 cm²/Vs) is much lower than an electron mobility (about 300 cm²/Vs), which can easily cause following problems.

(1) An electron concentration in a multiple quantum well (MQW) structure is much higher than the hole concentration, and some electrons even leak into a P-type semiconductor, causing a non-radiative recombination with holes provided by the P-type semiconductor, resulting in a decrease in hole injection efficiency.

(2) MQW LEDs generally have seven to ten quantum wells, with three to five quantum wells near the P-type semiconductor having higher light emitting brightness and five to seven quantum wells near a N-type semiconductor having lower light emitting brightness. The non-uniform distribution of holes and electrons restricts further improvement of the light emitting brightness of an LED epitaxial wafer.

(3) GaN materials with P-type dopants (such as Mg) in MQW LEDs are difficult to obtain a high hole concentration, resulting in the hole concentration in MQW being much lower than the electron concentration, thereby restricting the improvement of the light emitting brightness of the LED epitaxial wafer.

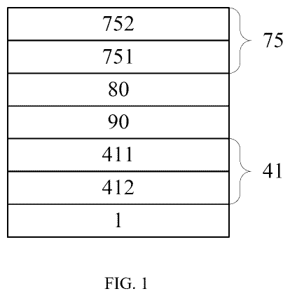

Referring to FIG. 1, FIG. 1 illustrates a schematic cross-sectional view of an epitaxial wafer.

The epitaxial wafer includes an N-type semiconductor 41, a quantum well light emitting layer 90 and a P-type semiconductor 75 sequentially stacked on a substrate 1.

In order to promote current diffusion, in the P-type semiconductor 75, a P-type current expansion layer 752 is disposed on a side of a P-type functional layer 751 for providing holes away from the quantum well light emitting layer 90, and in the N-type semiconductor 41, an N-type expansion layer 412 is disposed on a side of a N-type layer 411 for providing electrons away from the quantum well light emitting layer 90.

Further, in order to prevent leakage of electron into the P-type semiconductor 75, a current blocking layer 80 is disposed between the P-type semiconductor 75 and the quantum well light-emitting layer 90.

The current blocking layer 80 can suppress the leakage of electrons into the P-type semiconductor 75, but can also suppress the injection of holes in the P-type semiconductor 75 into the quantum well light emitting layer 90, resulting in a decrease in hole injection efficiency and non-uniform distribution of holes and electrons in the quantum well light emitting layer 90.

Therefore, an embodiment of the present disclosure provides an epitaxial wafer. The epitaxial wafer includes an N-type doped layer, a functional well structure and a P-type doped structure arranged in a stacked manner. The functional well structure is disposed between the N-type doped layer and the P-type doped structure, and the functional well structure includes a light emitting substructure and a transition substructure disposed between the light emitting substructure and the N-type doped layer.

According to the present disclosure, in the light emitting substructure, the multi-period light emitting layer is a multiple quantum well structure, and a barrier layer in the multiple quantum well structure has a weak blocking effect on holes, which can increase a migration distance of holes, thereby increasing the number of light emitting quantum wells and improving the light emitting efficiency of the epitaxial wafer. The transition substructure is disposed between the light emitting substructure and the N-type doped layer, thus an electron concentration of the light emitting substructure can be effectively controlled without an N-type current diffusion layer between the N-type doped layer and the light emitting substructure, which can improve a balance between electrons and holes in the light emitting substructure, thereby effectively improving the light emitting efficiency of the epitaxial wafer. Moreover, the electron concentration in the light emitting layer can be controlled through the transition substructure without an electron blocking layer between the P-type doped layer and the light emitting substructure, which can effectively increase a migration distance of holes and effectively improve the light emitting efficiency of the epitaxial wafer.

In order to make above objectives, features and advantages of the present disclosure more obvious and understandable, specific embodiments of the present disclosure will be clearly and completely described below in conjunction with the accompanying drawings.

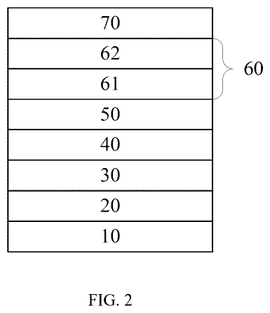

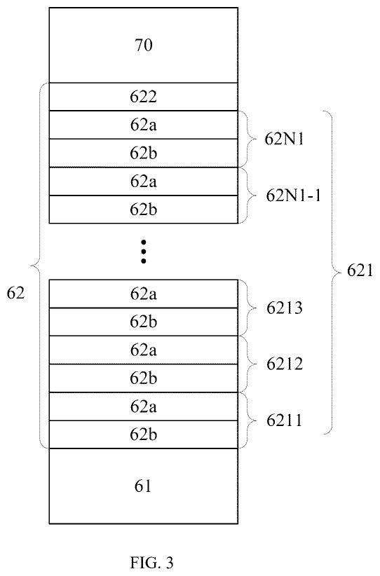

Referring to FIGS. 2 and 3, FIG. 2 illustrates a schematic cross-sectional view of an epitaxial wafer according to an embodiment of the present disclosure, and FIG. 3 illustrates a schematic cross-sectional view of a light emitting substructure of an epitaxial wafer according to an embodiment of the present disclosure.

As shown in FIG. 2, the epitaxial wafer includes an N-type doped layer 40, a functional well structure 60 and a P-type doped structure 70 arranged in a stacked manner. The functional well structure 60 is disposed between the N-type doped layer 40 and the P-type doped structure 70. The functional well structure 60 includes a light emitting substructure 62 and a transition substructure 61 disposed between the light emitting substructure 62 and the N-type doped layer 40. The following will describe a cross-sectional structure of the epitaxial wafer according to an embodiment of the present disclosure in detail with reference to the accompanying drawings.

The N-type doped layer 40 is configured to provide electrons, and the P-type doped structure 70 is configured to provide holes.

Different charge carriers provided by the N-type doped layer 40 and the P-type doped structure 70 respectively undergo radiative recombination in the light emitting substructure 62 to achieve light emitting.

Different charge carriers undergo radiative recombination in the light emitting substructure 62 of the functional well structure 60. The transition substructure 61 is disposed between the light emitting substructure 62 and the N-type doped layer 40, thus the electron concentration in the light emitting substructure 62 can be effectively controlled without setting an N-type current diffusion layer between the N-type doped layer 40 and the light emitting substructure 62, which can improve a balance between electrons and holes in the light emitting substructure 62. Moreover, the electron concentration in the light emitting substructure 62 can be controlled through the transition substructure 61 without an electron blocking layer between the P-type doped layer 70 and the light emitting substructure 62, which can effectively increase a migration distance of holes and effectively improve the light emitting efficiency of the epitaxial wafer.

Referring to FIG. 3, the similarities between this embodiment and previous embodiment will not be described again here. The difference between this embodiment and previous embodiment is that in some embodiments of the present disclosure, the light emitting substructure 62 includes a multi-period light emitting layer 621 disposed between the transition substructure 61 and the P-type doped structure 70.

In some embodiments of the present disclosure, the light emitting substructure 62 further includes a redundant barrier layer 622 disposed between the multi-period light emitting layer 621 and the P-type doped structure 70.

In the light emitting substructure 62, the radiative recombination of different charge carriers specifically occurs in the multi-period light emitting layer 621. The redundant barrier layer 622 disposed between the multi-period emitting layer 621 and the P-type doped structure 70 has a weak blocking effect on holes, which can increase the migration distance of holes and effectively improve the light emitting efficiency of the epitaxial wafer.

In some embodiments, the light emitting substructure 62 includes the multi-period light emitting layer 621 and the redundant barrier layer 622 disposed between the multi-period light emitting layer 621 and the P-type doped structure 70. The multi-period light emitting layer 621 and the redundant barrier layer 622 cooperate with each other to form the multiple quantum well structure.

In some embodiments of the present disclosure, the multi-period light emitting layer 621 has a multiple quantum well structure. The multi-period light emitting layer 621 includes a plurality of light emitting stack layers. Each emitting stack layer 621 includes a first barrier layer 62b and a first well layer 62a. The first barrier layer 62b is disposed between the first well layer 62a of the same light emitting stack layer and the N-type doped layer. The first barrier layer 62b is disposed near the N-type doped layer, and the first well layer 62a is disposed near the P-type doped layer.

The multi-period light emitting layer 621 has a multiple quantum well structure, and the first barrier layer 62b has a weak blocking effect on holes, which can increase the migration distance of holes, thereby increasing the number of light emitting quantum wells and improving the light emitting efficiency of the epitaxial wafer.

As shown in FIG. 3, the multi-period light emitting layer 621 includes a first light emitting stack layer 6211, a second light emitting stack layer 6212, a third light emitting stack layer 6213, . . . , and an N1th light emitting stack layer 621N1 arranged in a stacked manner in a direction pointing from the N-type doped layer 40 to the P-type doped structure 70.

In some embodiments, the multi-period light emitting layer 621 has five to ten light emitting stack layers. In some embodiments shown in FIG. 3, N1 is in a range from 5 to 10.

It should be noted that in some embodiments, the transition substructure 61 is disposed on a side of the first light emitting stack layer 6211 away from the P-type doped layer 70, and the first light emitting stack layer 6211 is disposed between the transition substructure 61 and the second light emitting stack layer 6212.

In some embodiments, the redundant barrier layer 622 is disposed on a side of the N1th light emitting stack layer 621N1 away from the N-type doped layer 40, and the N1th light emitting stack layer 621N1 is disposed between the redundant barrier layer 622 and the (N1-1)th light emitting stack layer 621N1-1.

In some embodiments, the functional well structure 60 is a group III-V multiple quantum well structure. In some embodiments shown in FIG. 3, the epitaxial wafer is used with a display device, and the functional well structure 60 is a group III-V multiple quantum well structure.

In other embodiments of the present disclosure, the functional well structure may also be a group II-VI multiple quantum well structure.

In some embodiments, the first well layer 62a is an In_{w}Ga_{1-w}N layer, where 0.1≤w≤0.4. The first barrier layer 62b is an N-type doped GaN layer. For example, the first barrier layer 62b includes an N-type dopant, such as Si or Ge.

In some embodiments, the first well layer 62a has a thickness ranging from 2.0 nm to 4.0 nm, and the first barrier layer 62b has a thickness ranging from 9.0 nm to 14.0 nm.

In some embodiments, in the multi-period light emitting layer 621, the first barrier layers 62b of different light emitting stack layers have an equal thickness, and the first well layers 62a of different light emitting stack layers have an equal thickness.

Still referring to FIG. 3, the redundant barrier layer 622 can block electrons from entering the P-type doped structure, which can avoid non-radiative recombination of electrons and holes in the P-type doped structure and prevent affecting the light emitting efficiency of the epitaxial wafer, thereby increasing the hole concentration in the light emitting substructure 62 and improving a radiative recombination rate in the light emitting substructure 62.

The redundant barrier layer 622 is disposed on a side of the N1th light emitting stack layer away from the N-type doped layer. The redundant barrier layer 622 serves as a potential barrier layer and, together with the first well layer 62a and the first barrier layer 612b in the N1th light emitting stack layer, forms the quantum well closest to the P-type doped structure in the light emitting substructure 62. The redundant barrier layer 622 has a weak blocking effect on holes, which can increase the migration distance of holes, thereby increasing the number of light emitting quantum wells and improving the light emitting efficiency of the epitaxial wafer.

In some embodiments, the redundant barrier layer 622 is an intrinsic layer. The redundant barrier layer 622 is not doped. The redundant barrier layer 622 does not contain doped atoms. The redundant barrier layer 622 can also prevent the diffusion of the P-type dopant in the P-type doped structure into the light emitting substructure 62, effectively improving the stability and performance of the light emitting substructure 62.

In some embodiments, the functional well structure 60 is a group III-V multiple quantum well structure. The redundant barrier layer 622 is a group III-V intrinsic layer. In some embodiments shown in FIG. 3, the functional well structure 60 is group III-V multiple quantum well structure, and the redundant barrier layer 622 is a group III-V intrinsic layer.

As an example, the first barrier layer 62b is an N-type doped GaN layer, and the redundant barrier layer 622 is a GaN intrinsic layer. The redundant barrier layer 622 is an undoped GaN layer. The material of the redundant barrier layer 622 is undoped GaN.

In other embodiments of the present disclosure, the functional well structure may also be a group II-VI multiple quantum well structure. The redundant barrier layer is a group II-VI intrinsic layer. The redundant barrier layer is an intrinsic layer of a material of the first barrier layer. The material of the redundant barrier layer is the same as that of the undoped first barrier layer.

In some embodiments, the redundant barrier layer 622 serves as a potential barrier layer. The thickness of the redundant barrier layer 622 is the same as that of the first barrier layer 62b. For example, the thickness of the redundant barrier layer 622 is in a range from 9.0 nm to 14.0 nm.

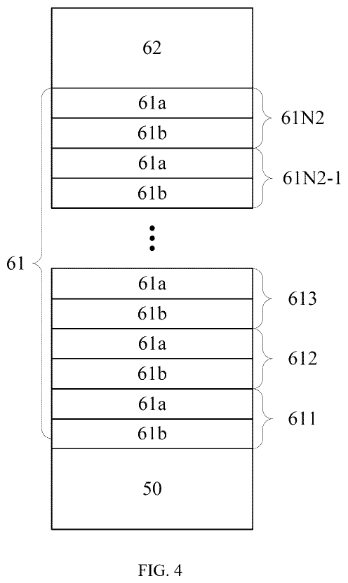

Referring to FIG. 4, FIG. 4 illustrates a schematic cross-sectional view of a transition substructure of an epitaxial wafer according to an embodiment of the present disclosure.

The similarities between this embodiment and previous embodiments will not be described again here. The difference between this embodiment and previous embodiments is that in some embodiments of the present disclosure, the transition substructure 61 includes a plurality of transition stack layers. Each transition stack layer includes a second barrier layer 61b and a second well layer 61a. The second barrier layer 61b is disposed between the second well layer 61a of the same transition stack layer and the N-type doped layer 40. The second barrier layer 61b is disposed near the N-type doped layer, and the second well layer 61a is disposed near the P-type doped layer.

The transition substructure 61 is also a multiple quantum well structure. The transition substructure 61 includes the plurality of transition stack layers can effectively control the electron concentration in the light emitting substructure 62 and improve the balance of electrons and holes in the multi-period emitting layer.

As shown in FIG. 4, the transition substructure 61 includes a first transition stack layer 611, a second transition stack layer 612, a third transition stack layer 613, . . . , and an N2th transition stack layer 61N2 sequentially arranged in a stacked manner in the direction pointing from the N-type doped layer to the P-type doped structure.

In some embodiments, the transition substructure 61 has three to five transition stack layers. In some embodiments shown in FIG. 4, N2 is in a range from 3 to 5.

It should be noted that in some embodiments, a stress adjustment structure 50 is disposed on a side of the first transition stack layer 611 away from the P-type doped layer. The first transition layer stacked 611 is disposed between the stress adjustment structure 50 and the second transition stack layer 612.

In addition, the light emitting substructure 62 is disposed on a side of the N2th transition stack layer 61N2 away from the N-type doped layer, and the N2th transition stack layer 61N2 is disposed between the light emitting substructure 62 and the (N2-1)th transition stack layer 61N2-1.

In some embodiments, the functional well structure is a group III-V multiple quantum well structure, and the second well layer 61a is an InₓGa₁₋ₓN layer, where 0<x≤0.3. The second barrier layer 61b is an N-type doped Al_{y}Ga_{1-y}N layer, where 0≤y≤0.2. For example, the second barrier layer 61b includes an N-type dopant, such as Si or Ge.

In some embodiments, the second barrier layer 61b is an N-type doped Al_{y}Ga_{1-y}N layer, where 0<y≤0.2. A component content of Al in the second barrier layer 61b on a side away from the N-type doped layer 40 is greater than the component content of Al in the second barrier layer 61b on a side adjacent to the N-type doped layer 40.

Al has a large bandgap width. The higher the component content of Al in the AlyGal-yN layer is, the larger the bandgap width of the AlyGal-yN layer is, the lower the probability of electron transition to a conduction band is, the better the effect of blocking electron diffusion is, and the slower the electron diffusion rate is. The closer to the light emitting substructure 62, the higher the component content of Al, which can better reduce the electron concentration and electron velocity of electrons entering the light emitting substructure 62, allowing more electrons to undergo radiative recombination with holes in the light emitting substructure 62 and reduce electron loss.

As an example, in the direction away from the N-type doped layer 40, the component content of Al in the second barrier layer 61b increases layer by layer. In the transition substructure 61, in the adjacent two transition stack layers, the component content of Al in the second barrier layer 61b in the transition stack layer on the side away from the N-type doped layer 40 is greater than the component content of Al in the second barrier layer 61b in the transition stack layer on the side adjacent to the N-type doped layer 40. However, the component content of Al in the same second barrier layer 61b is uniform.

As shown in FIG. 4, in the transition substructure 61, the component content of Al in the second barrier layer 61b of the second transition stack layer 612 is greater than the component content of Al in the second barrier layer 61b of the first transition stack layer 611; the component content of Al in the second barrier layer 61b of the third transition stack layer 613 is greater than the component content of Al in the second barrier layer 61b of the second transition stack layer 612; . . . , the component content of Al in the second barrier layer 61b of the N2th transition stack layer 61N2 is greater than the component content of Al in the second barrier layer 61b of the (N2-1)th transition stack layer 61N2-1. However, the component content of Al in the second barrier layer 61b of the first transition stack layer 611 is uniform, the component content of Al in the second barrier layer 61b of the second transition stack layer 612 is uniform, the component content of Al in the second barrier layer 61b of the third transition stack layer 613, . . . , and the component content of Al in the second barrier layer 61b of the N2th transition stack layer 61N2 is uniform.

In other embodiments, the component content of Al in the second barrier layer gradually increases in the direction away from the N-type doped layer. In the transition substructure, in two adjacent transition stack layers, the component content of Al in the second barrier layer of the transition stack layer on the side away from the N-type doped layer is greater than the component content of Al in the second barrier layer of the transition stack layer on the side adjacent to the N-type doped layer. In the same second barrier layer, the component content of Al is also non-uniform, and in the same second barrier layer, the component content of Al on the side away from the N-type doped layer is greater than the component content of Al on the side adjacent to the N-type doped layer.

In some embodiments, the second well layer 61a has a thickness ranging from 2.0 nm to 4.0 nm, and the second barrier layer 61b has a thickness ranging from 7.0 nm to 12.0 nm.

In some embodiments, in the transition substructure 61, the second barrier layers 61b of different transition stack layers have an equal thickness, and the second well layers 61a of different transition stack layers have an equal thickness.

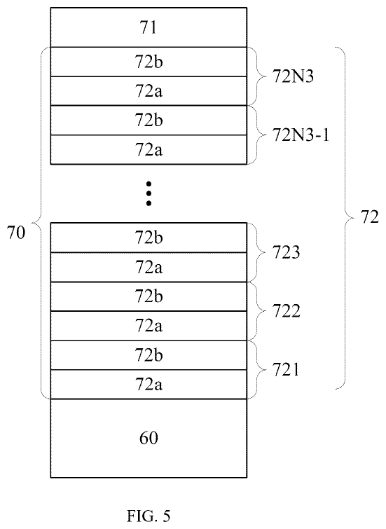

Referring to FIG. 5, FIG. 5 illustrates a schematic cross-sectional view of a p-type doped structure of an epitaxial wafer according to an embodiment of the present disclosure.

The similarities between this embodiment and previous embodiments will not be described again here. The difference between this embodiment and previous embodiments is that in some embodiments of the present disclosure, the P-type doped structure 70 includes a P-type layer 71 and a multi-period doped layer 72 disposed between the P-type layer 71 and the functional well structure 60.

The P-type doped structure 70 includes the multi-period doped layer 72, which can increase the effective hole concentration in the P-type doped structure 70, thereby improving the hole concentration in the light emitting substructure 62 and improving the balance of electrons and holes in the light emitting substructure 62, and enhancing the brightness of the epitaxial wafer.

In addition, the multi-period doped layer 72 can also reduce an annealing temperature of subsequent annealing process, effectively control the influence of the annealing process on potential wells in the functional well structure, and reduce the damage of the high temperature during the annealing process to the potential wells in the first well layer 62a and the first barrier layer 62b of the multi-period emitting layer 621 in the light emitting substructure structure 62.

In some embodiments, the multi-period doped layer 72 is also a multiple quantum well structure. The multi-period doped layer 72 includes a plurality of doped stack layers. Each doped stack layer includes a ternary doped layer 72a and a binary doped layer 72b. The ternary doped layer 72a is disposed between the binary doped layer 72b of the same doped stack layer and the functional well structure 60.

In some embodiments shown in FIG. 5, the multi-period doped layer 72 includes a first doped stack layer 721, a second doped stack layer 722, a third doped stack layer 723, . . . , and a N3th doped stack layer 72N3 sequentially stacked in the direction pointing from the N-type doped layer to the P-type doped structure.

In some embodiments, the multi-period doped layer 72 includes at least five doped stack layers. In some embodiments shown in FIG. 5, N3 is in a range greater than or equal to 5.

It should be noted that in some embodiments, the light emitting substructure 62 is disposed on a side of the first doped stack layer 721 facing the N-type doped layer 40, and the first doped stack layer 721 is disposed between the light emitting substructure 62 and the second doped stack layer 722.

In addition, in some embodiments, the P-type layer 71 is disposed on a side of the N3th doped stack layer 72N3 away from the N-type doped layer 40, and the N3th doped stack layer 72N3 is disposed between the P-type layer 71 and the (N3-1)th doped stack layer 72N3-1.

In some embodiments, the concentration of the P-type dopant in the P-type doped structure 70 is in a range from 3×10¹⁸ atoms/cm³ to 5×10²⁰ atoms/cm³. The concentration of the P-type dopant in the P-type layer 71 and the multi-period doped layer 72 is in a range from 3×10¹⁸ atoms/cm³ to 5×10²⁰ atoms/cm³. Setting the concentration of the P-type dopant in the P-type doped structure 70 within the above range can effectively increase the hole concentration, and within this concentration range, the P-type dopant is less likely to agglomerate to affect the hole concentration.

In some embodiments, the concentration of the P-type dopant in the multi-period doped layer 72 on the side away from the N-type doped layer 40 is greater than the concentration of the P-type dopant in the multi-period doped layer 72 on the side adjacent to the N-type doped layer 40.

The P-type dopant is non-uniformly distributed in the multi-period doped layer 72. The farther away from the light emitting substructure 62, the higher the concentration of the P-type dopant; the closer to the light emitting substructure 62, the lower the concentration of the P-type dopant, which can effectively increase the hole concentration in the P-type doped structure 70.

In some embodiments, the concentration of the P-type dopant in the multi-period doped layer 72 increases periodically in a direction away from the N-type doped layer 40. In the multi-period doped layer 72, in adjacent two doped stack layers, the concentration of the P-type dopant in the doped stack layer on the side away from the N-type doped layer is higher than the concentration of the P-type dopant in the doped stack layer on the side adjacent to the N-type doped layer.

As shown in FIG. 5, in the multi-period doped layer 72, the concentration of the P-type dopant in the second doped stack layer 722 is higher than the concentration of the P-type dopant in the first doped stack layer 721; the concentration of the P-type dopant in the third doped stack layer 723 is higher than that the concentration of the P-type dopant in the second doped layer 722; . . . ; and the concentration of the P-type dopant in the N3th doped stack layer 72N3 is higher than the concentration of the P-type dopant in the (N3-1)th doped stack layer 72N3-1.

In some embodiments, the concentration of the P-type dopant is uniform in the same doped stack layer. Specifically, the distribution of the P-type dopant is uniform in the ternary doped layer 72a and the binary doped layer 72b in the same doped stack layer. That is, the concentration of the P-type dopant is equal everywhere in the ternary doped layer 72a and the binary doped layer 72b of the same doped stack layer.

As shown in FIG. 5, the P-type dopant is uniformly distributed in the first doped stack layer 721, the second doped stack layer 722, the third doped stack layer 723, . . . , and the N3th doped layer 72N3, respectively. The concentration of the P-type dopant is equal everywhere in the ternary doped layer 72a and the binary doped layer 72b of the first doped stack layer 721, in the ternary doped layer 72a and the binary doped layer 72b of the second doped stack layer 722, in the ternary doped layer 72a and the binary doped layer 72b of the third doped stack layer 723, . . . , and in the ternary doped layer 72a and the binary doped layer 72b of the N3th doped stack layer 72N3.

In other embodiments, in the same doped stack layer, the concentration of the P-type dopant increases layer by layer in the direction away from the N-type doped layer. In the same doped stack layer, the concentration of the P-type dopant in the binary doped layer is higher than the concentration of the P-type dopant in the ternary doped layer. But, in the binary doped layer and the ternary doped layer, the distribution of the P-type dopant in each layer is uniform. The concentration of the P-type dopant is equal everywhere in the binary doped layer, and the concentration of the P-type dopant is equal everywhere in the ternary doped layer.

For example, the concentration of the P-type dopant in the binary doped layer of the first doped stack layer is higher than the concentration of the P-type dopant in the ternary doped layer of the first doped stack layer, but the concentration of the P-type dopant in the binary doped layer of the first doped stack layer is equal everywhere, and the concentration of the P-type dopant in the ternary doped layer of the first doped stack layer is equal everywhere; the concentration of the P-type dopant in the binary doped layer of the second doped stack layer is higher than the concentration of the P-type dopant in the ternary doped layer of the second doped stack layer, but the concentration of the P-type dopant in the binary doped layer of the second doped stack layer is equal everywhere, and the concentration of the P-type dopant in the ternary doped layer of the second doped stack layer is equal everywhere; the concentration of the P-type dopant in the binary doped layer of the third doped stack layer is higher than the concentration of the P-type dopant in the ternary doped layer of the third doped stack layer, but the concentration of the P-type dopant in the binary doped layer of the third doped stack layer is equal everywhere, and the concentration of the P-type dopant in the ternary doped layer of the third doped stack layer is equal everywhere; . . . ; the concentration of the P-type dopant in the binary doped layer of the N3th doped stack layer is higher than the concentration of the P-type dopant in the ternary doped layer of the N3th doped stack layer, but the concentration of the P-type dopant in the binary doped layer of the N3th doped stack layer is equal everywhere, and the concentration of the P-type dopant in the ternary doped layer of the N3th doped stack layer is equal everywhere.

In other embodiments, in the same doped stack layer, the concentration of the P-type dopant gradually increases in the direction away from the N-type doped layer. In the same doped stack layer, the concentration of the P-type dopant in the binary doped layer is higher than the concentration of the P-type dopant in the ternary doped layer. Moreover, the distribution of the P-type dopant is non-uniformly in both the binary doped layer and the ternary doped layer. In the binary doped layer, the concentration of the P-type dopant gradually increases in the direction away from the N-type doped layer. In the ternary doped layer, the concentration of the P-type dopant gradually increases in the direction away from the N-type doped layer.

For example, the concentration of the P-type dopant in the binary doped layer of the first doped stack layer is higher than the concentration of the P-type dopant in the ternary doped layer of the first doped stack layer, and the concentration of the P-type dopant in both the binary doped layer of the first doped stack layer and the ternary doped layer of the first doped stack layer gradually increases in the direction away from the N-type doped layer; the concentration of the P-type dopant in the binary doped layer of the second doped stack layer is higher than the concentration of the P-type dopant in the ternary doped layer of the second doped stack layer, and the concentration of the P-type dopant in both the binary doped layer of the second doped stack layer and the ternary doped layer of the second doped stack layer gradually increases in the direction away from the N-type doped layer; . . . ; the concentration of the P-type dopant in the binary doped layer of the N3th doped stack layer is higher than the concentration of the P-type dopant in the ternary doped layer of the N3th doped stack layer, and the concentration of the P-type dopant in both the binary doped layer of the N3th doped stack layer and the ternary doped layer of the N3th doped stack layer gradually increases in the direction away from the N-type doped layer.

In some embodiments shown in FIG. 5, the multi-period doped layer 72 is a group III-V multiple quantum well structure, the ternary doped layer 72a is a P-type doped InGaN layer, and the binary doped layer 72b is a P-type doped GaN layer. For example, both the InGaN layer and the GaN layer have P-type dopant, such as at least one of Mg and Zn.

In some embodiments, a component content of Ga in the multi-period doped layer 72 on the side away from the N-type doped layer 40 is less than that the component content of Ga in the multi-period doped layer 72 adjacent to the N-type doped layer 40, and a component content of In in the InGaN layer of the multi-period doped layer 72 on the side away from the N-type doped layer 40 is greater than the component content of In in the InGaN layer of the multi-period doped layer 72 adjacent to the N-type doped layer 40.

The component content of Ga and the component content of In in the multi-period doped layer 72 are non-uniformly distributed. The farther away from the light emitting substructure 62, the higher the component content of In and the lower the component content of Ga; and the closer to the light emitting substructure 62, the lower the component content of In and the higher the component content of Ga, which can effectively increase the hole concentration in the P-type doped structure 70.

In some embodiments, in the direction away from the N-type doped layer 40, the component content of Ga in the multi-period doped layer 72 decreases periodically and the component content of In increases periodically. In the multi-period doped layer 72, in adjacent two doped stack layers, the component content of Ga in the doped stack layer on the side away from the N-type doped layer is lower than the component content of Ga in the doped stack layer on the side adjacent to the N-type doped layer, and the component content of In in the doped stack layer on the side away from the N-type doped layer is higher than the component content of In in the doped stack layer on the side adjacent to the N-type doped layer.

As shown in FIG. 5, in the multi-period doped layer 72, the component content of Ga in the second doped layer 722 is lower than the component content of Ga in the first doped layer 721, and the component content of In in the second doped layer 722 is higher than the component content of In in the first doped layer 721; the component content of Ga in the third doped layer 723 is lower than the component content of Ga in the second doped layer 722, and the component content of In in the third doped layer 723 is higher than the component content of In in the second doped layer 722; . . . ; the component content of Ga in the N3th doped stack 72N3 is lower than the component content of Ga in the (N3-1)th doped stack layer 72N3-1, and the component content of In in the N3th doped layer 72N3 is higher than the component content of In in the (N3-1)th doped stack layer 72N3-1.

In some embodiments, in the same doped stack layer, the component content of Ga is uniform, and the component content of In in the InGaN layer is uniform. Specifically, in the InGaN layer and the GaN layer of the same doped stack layer, the component content of Ga is uniform. In the InGaN layer of the same doped stack layer, the component content of In in the InGaN layer is uniform. That is, in the InGaN layer and the GaN layer of the same doped stack layer, the distribution of Ga component is uniform, and in the InGaN layer of the same doped stack layer, the distribution of In component is uniform.

As shown in FIG. 5, the distribution of Ga component is uniform in the InGaN layer and the GaN layer of the first doped stack layer 721, in the InGaN layer and the GaN layer of the second doped stack layer 722, in the InGaN layer and the GaN layer of the third doped stack layer 723, . . . , and in the InGaN layer and the GaN layer of the N3th doped stack layer 72N3, respectively. The distribution of In component is uniform in the InGaN layer of the first doped stack layer 721, in the InGaN layer of the second doped stack layer 722, in the InGaN layer of the third doped stack layer 723, . . . , and in the InGaN layer of the N2th doped stack layer 72N2.

In other embodiments, the component content of Ga decreases layer by layer in the direction away from the N-type doped layer in the same doped stack layer. Specifically, in the same doped stack layer, the component content of Ga in the GaN layer is lower than the component content of Ga in the InGaN layer. However, the component content of Ga in the GaN layer and the component content of Ga in the InGaN layer are both uniform. That is, the distribution of Ga component in the GaN layer is uniform, and the distribution of Ga component in the InGaN layer is uniform.

For example, in the first doped stack layer, the component content of Ga in the GaN layer is lower than the component content of Ga in the InGaN layer; in the second doped stack layer, the component content of Ga in the GaN layer is lower than the component content of Ga in the InGaN layer; in the third doped stack layer, the component content of Ga in the GaN layer is lower than the component content of Ga in the InGaN layer; . . . ; In the N2th doped stack layer, the component content of Ga in the GaN layer is lower than the component content of Ga in the InGaN layer. However, the component content of Ga is uniform in the GaN layer and the InGaN layer of the first doped stack layer, in the GaN layer and the InGaN layer of the second doped stack layer, in the GaN layer and the InGaN layer of the third doped stack layer, . . . , and in the GaN layer and the InGaN layer of the N2th doped stack layer, respectively. That is, the distribution of Ga component is uniform in the GaN layer and the InGaN layer of the first doped stack layer, in the GaN layer and the InGaN layer of the second doped stack layer, in the GaN layer and the InGaN layer of the third doped stack layer, . . . , and in the GaN layer and the InGaN layer of the N2th doped stack.

In other embodiments, in the same doped stack layer, the component content of Ga gradually decreases and the component content of In in the InGaN layer gradually increases in the direction away from the N-type doped layer. Specifically, in the InGaN layer and the GaN layer of the same doped stack layer, the component content of Ga in the GaN layer is lower than the component content of Ga in the InGaN layer, and the component content of Ga in both the GaN layer and the InGaN layer gradually decreases. In the direction away from the N-type doped layer, the component content of Ga in the GaN layer and the component content of Ga in the InGaN layer both gradually decrease. In addition, the component content of In in the InGaN layer gradually increases. In addition, in the InGaN layer of the same doped stack layer, the component content of In is non-uniform, and the component content of In gradually increases in the direction away from the N-type doped layer.

For example, in the first doped stack layer, the component content of Ga in the GaN layer is lower than the component content of Ga in the InGaN layer; in the second doped stack layer, the component content of Ga in the GaN layer is lower than the component content of Ga in the InGaN layer; in the third doped stack layer, the component content of Ga in the GaN layer is lower than the component content of Ga in the InGaN layer; . . . ; in the N2th doped stack layer, the component content of Ga in the GaN layer is lower than the component content of Ga in the InGaN layer. The component content of Ga is non-uniform in the GaN layer and the InGaN layer of the first doped stack layer, in the GaN layer and the InGaN layer of the second doped stack layer, in the GaN layer and the InGaN layer of the third doped stack layer, . . . , and in the GaN layer and the InGaN layer of the N2th doped stack layer. The component content of Ga gradually decreases in the direction away from the N-type doped layer in the GaN layer and the InGaN layer of the first doped stack layer, in the GaN layer and the InGaN layer of the second doped stack layer, in the GaN layer and the InGaN layer of the third doped stack layer, . . . , and in the GaN layer and the InGaN layer of the N2th doped stack layer. In addition, the component content of In in the InGaN layer of the second doped stack layer is higher than the component content of In in the InGaN layer of the first doped stack layer; the component content of In in the InGaN layer of the third doped stack layer is higher than the component content of In in the InGaN layer of the second doped stack layer; . . . ; the component content of In in the InGaN layer of the N2th doped stack layer is higher than the component content of In in the InGaN layer of the (N2-1)th doped stack layer. Moreover, the component content of In is non-uniform in the InGaN layers of the first doped stack layer, the second doped stack layer, the third doped stack layer and the N2th doped stack layer. Moreover, the component content of In gradually increases in the direction away from the N-type doped layer in the InGaN layer of the first doped stack layer, in the InGaN layer of the second doped stack layer, in the InGaN layer of the third doped stack layer, . . . , and in the InGaN layer of the N2th doped stack layer.

In some embodiments, the doped stack layer has a thickness ranging from 5 nm to 10 nm.

In some embodiments, different doped stack layers in the multi-period doped layer 72 have an equal thickness. In addition, in the multi-period doped layer 72, the ternary doped layer 72a of different doped stack layers have an equal thickness, and the binary doped layer 72b of different doped stack layers have an equal thickness.

Still referring to FIG. 5, the P-type layer 71 serves as a P electrode of the epitaxial wafer to achieve electrical connection.

In some embodiments of the present disclosure, the functional well structure is a group III-V multiple quantum well structure, and the P-type layer 71 is an InGaN layer doped with a P-type dopant.

The InGaN material of the P-type layer 71 has a narrow bandgap and good conductivity. After doped with the P-type dopant, the InGaN layer doped with the P-type dopant can further improve the conductivity of the InGaN layer, increase the hole concentration in the P-type doped structure 70, increase the concentration of holes that undergo radiation recombination with electrons in the light emitting substructure 62, and improve the light emitting brightness of the epitaxial wafer.

Referring to FIG. 2, in some embodiments of the present disclosure, the N-type doped layer 40 of the epitaxial wafer has a single-layer structure or a multi-layer composite layer structure. For example, the functional well structure is a group III-V multiple quantum well structure, and the N-type doped layer 40 includes at least one of a GaN layer, an AlGaN layer and an AlInGaN layer.

The N-type doped layer 40 includes an N-type dopant. In some embodiments, the concentration of the N-type dopant in the N-type doped layer 40 is in a range from 8×10¹⁸ atoms/cm³ to 1×10²¹ atoms/cm³.

In some embodiments, the N-type doped layer 40 has a thickness ranging from 2.0 μm to 4.0 μm.

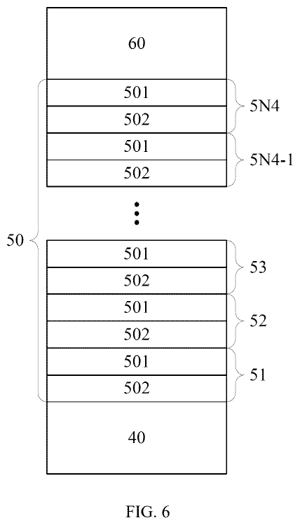

Referring to FIG. 6, FIG. 6 illustrates a schematic cross-sectional view of a stress adjustment structure of an epitaxial wafer according to an embodiment of the present disclosure.

The similarities between this embodiment and previous embodiments will not be described again here. The difference between this embodiment and previous embodiments is that in some embodiments of the present disclosure, the functional well structure 60 further includes a stress adjustment structure 50 disposed between the N-type doped layer 40 and the transition substructure 61.

The stress adjustment structure 50 can shield non-radiative recombination caused by an extension dislocation on a side of the stress adjustment structure 50 away from the P-type doped structure 70.

In some embodiments of the present disclosure, the stress adjustment structure 50 is a multiple quantum well structure. The stress adjustment structure 50 includes a plurality of stress adjustment stack layers, including a third well layer 501 and a third barrier layer 502. The third barrier layer 502 is disposed between the third well layer 501 of the same stress adjustment stack layer and the N-type doped layer 40. The third barrier layer 502 is disposed adjacent to the N-type doped layer 40, and the third well layer 501 is disposed adjacent to the P-type doped structure 70.

During electron injecting process, the stress adjustment structure of the functional well structure can also slow down a lateral (perpendicular to a direction of electron injection) diffusion of electrons, which can avoid electron loss caused by premature lateral diffusion of electrons, thereby increasing the concentration of electrons entering the light emitting substructure and undergoing radiation recombination with holes, and improving utilization efficiency of electrons.

As shown in FIG. 6, the stress adjustment structure 50 includes a first stress adjustment stack layer 51, a second stress adjustment stack layer 52, a third stress adjustment stack layer 53, . . . , and a N4th stress adjustment stack layer 5N4 sequentially stacked in the direction pointing from the N-type doped layer to the P-type doped structure.

In some embodiments of the present disclosure, the stress adjustment structure 50 includes at least nine stress adjustment stack layers. In some embodiments shown in FIG. 6, N4 is in a range greater than or equal to nine.

It should be noted that in some embodiments, the N-type doped layer 40 is disposed on a side of the first stress adjustment stack layer 51 away from the P-type doped layer 70, and the first stress adjustment stack layer 51 is disposed between the N-type doped layer 40 and the second stress adjustment stack layer 52.

In addition, in some embodiments, the transition substructure 61 is disposed on a side of the N4th stress adjustment stack layer 5N4 away from the N-type doped layer 40, and the N4th stress adjustment stack layer 5N4 is disposed between the transition substructure 61 and the (N4-1)th stress adjustment stack layer 5N4-1.

In some embodiments of the present disclosure, the functional well structure is a group III-V multiple quantum well structure. The third well layer 501 is an In_{z}Ga_{1-z}N layer, where 0<z≤0.1, and the third barrier layer 502 is a GaN layer.

In some embodiments of the present disclosure, the third well layer 501 has a thickness ranging from 1.0 nm to 2.5 nm, and the third barrier layer 502 has a thickness ranging from 2.0 nm to 4.0 nm.

In some embodiments, in the stress adjustment structure 50, the third well layers 501 of different stress adjustment stack layers have an equal thickness, and the third barrier layers 502 of different stress adjustment stack layers have an equal thickness.

Still referring to FIG. 2, in some embodiments of the present disclosure, the epitaxial wafer further includes an undoped layer 30, a buffer layer 20 and a substrate 10. The substrate 10 is disposed on a side of the N-type doped layer 40 away from the P-type doped structure 70. The buffer layer 20 is disposed between the substrate 10 and the N-type doped layer 40. The undoped layer 30 is disposed between the buffer layer 20 and the N-type doped layer 40. The substrate 10 is configured to provide mechanical support.

In some embodiments, the substrate 10 may be a single-material substrate, or a multi-material composite substrate. For example, the substrate 10 includes at least one of a sapphire substrate, a GaN substrate, an AlN substrate, a Si substrate and a SiC substrate.

The undoped layer 30 is configured for transition to better form the N-type doped layer. The material of the undoped layer 30 corresponds to the material of the N-type doped layer 40.

In some embodiments, the undoped layer 30 has a single-layer structure or a multi-layer composite structure. For example, the undoped layer 30 includes at least one of a GaN layer, an AlGaN layer and an AlInGaN layer. Specifically, the undoped layer 30 has a thickness ranging from 2.0 μm to 4.0 μm.

The buffer layer 20 is configured to reduce a dislocation density of subsequent epitaxial functional layers (i.e., the N-type doped layer 40, the functional well structure 60 and the P-type doped structure 70) to improve growth quality of the epitaxial functional layers. The material of the buffer layer 20 corresponds to the material of the N-type doped layer 40.

In some embodiments, the buffer layer 20 has a single-layer structure or a multi-layer composite structure. For example, the buffer layer 20 includes at least one of an AlN layer, a GaN layer, an AlGaN layer and an AlInGaN layer. Specifically, the buffer layer 20 has a thickness ranging from 15 nm to 50 nm.

Correspondingly, referring to FIGS. 2 and 3, an embodiment of the present disclosure also provides an epitaxial wafer. The epitaxial wafer includes an N-type doped layer 40, a functional well structure 60, and a P-type doped structure 70 stacked sequentially. The functional well structure 60 includes a light emitting substructure 62, and the light emitting substructure 62 includes a redundant barrier layer 622. The redundant barrier layer 622 is disposed between the N-type doped layer 40 and the P-type doped structure 70.

In some embodiments, the N-type doped layer 40, the functional well structure 60 and the P-type doped structure 70 are the same or similar to the embodiments of the epitaxial wafer described above. The specific technical solutions of the N-type doped layer 40, the functional well structure 60 and the P-type doped structure 70 can refer to the embodiments of the epitaxial wafer described above.

The redundant barrier layer 622 has the function of blocking electrons, avoiding a high electron concentration in the multiple quantum well structure. Electrons in the multiple quantum well structure migrate to the P-type doped structure 70, and have a non-radiative recombination with holes in the P-type doped structure, which affects the light emitting efficiency of the epitaxial wafer. The transition substructure is disposed between the light emitting substructure 62 and the N-type doped layer 40, thus an electron concentration of the light emitting layer can be effectively controlled without an N-type current diffusion layer between the N-type doped layer 40 and the light emitting substructure, which can improve a balance between electrons and holes in the light emitting layer, thereby effectively improving the light emitting efficiency of the epitaxial wafer. Moreover, the electron concentration in the light emitting layer can be controlled through the transition substructure without an electron blocking layer between the P-type doped structure 70 and the light emitting substructure 62, which can effectively increase a migration distance of holes and effectively improve the light emitting efficiency of the epitaxial wafer.

In some embodiments, as shown in FIGS. 2 and 3, the light emitting substructure 62 further includes a multi-period light emitting layer 621 disposed between the N-type doped layer 40 and the redundant barrier layer 622. The multi-period light emitting layer 621 is the same or similar to the embodiments of the epitaxial wafer described above. The specific technical solution of the multi-period light emitting layer 621 can refer to the embodiments of the epitaxial wafer described above.

In some embodiments, as shown in FIGS. 2 and 5, the P-type doped structure 70 includes a P-type layer 71 and a multi-period doped layer 72 disposed between the P-type layer 71 and the functional well structure 60. The P-type layer 71 and the multi-period doped layer 72 are the same or similar to the embodiments of the epitaxial wafer described above. The specific technical solutions of the P-type layer 71 and the multi-period doped layer 72 can refer to the embodiments of the epitaxial wafer described above.

In some embodiments, as shown in FIGS. 2 and 6, the functional well structure 60 further includes a stress adjustment structure 50 disposed between the N-type doped layer 40 and the light emitting substructure 60. The stress adjustment structure 50 is the same or similar to the embodiments of the epitaxial wafer described above. The specific technical solution of the stress adjustment structure 50 can refer to the embodiments of the epitaxial wafer described above.

In some embodiments, as shown in FIG. 2, the epitaxial wafer further includes an undoped layer 30, a buffer layer 20 and a substrate 10. The substrate 10 is disposed on a side of the N-type doped layer 40 away from the P-type doped structure 70. The buffer layer 20 is disposed between the substrate 10 and the N-type doped layer 40. The undoped layer 30 is disposed between the buffer layer 20 and the N-type doped layer 40. The undoped layer 30, the buffer layer 20 and the substrate 10 are the same or similar to the embodiments of the epitaxial wafer described above. The specific technical solutions of the undoped layer 30, the buffer layer 20 and the substrate 10 can refer to the embodiments of the epitaxial wafer described above.

In addition, the present disclosure also provides a display device.

The display device includes an epitaxial wafer according to some embodiments of the present disclosure.

The specific technical solution of the epitaxial wafer can refer to the embodiments of the epitaxial wafer described above, which will not be repeated here.

In the epitaxial wafer of the present disclosure, the functional well structure disposed between the N-type doped layer and the P-type doped structure includes a light emitting substructure and a transition substructure disposed between the light emitting substructure and the N-type doped layer. In the light emitting substructure, the multi-period light emitting layer is a multiple quantum well structure, and a barrier layer in the multiple quantum well structure and the redundant barrier layer have a weak blocking effect on holes, which can increase a migration distance of holes, thereby increasing the number of light emitting quantum wells and improving the light emitting efficiency of the epitaxial wafer. The transition substructure is disposed between the light emitting substructure and the N-type doped layer, thus an electron concentration of the light emitting layer can be effectively controlled without an N-type current diffusion layer between the N-type doped layer and the light emitting substructure, which can improve a balance between electrons and holes in the light emitting layer, thereby effectively improving the light emitting efficiency of the epitaxial wafer. Moreover, the electron concentration in the light emitting layer can be controlled through the transition substructure without an electron blocking layer between the P-type doped layer and the light emitting substructure, which can effectively increase a migration distance of holes and effectively improve the light emitting efficiency of the epitaxial wafer.

The epitaxial wafer of the present disclosure has higher light emitting efficiency and greater light emitting brightness, which can effectively improve a display effect of the display device and effectively improve an energy consumption of the display device.

In addition, the present disclosure also provides a method for preparing an epitaxial wafer.

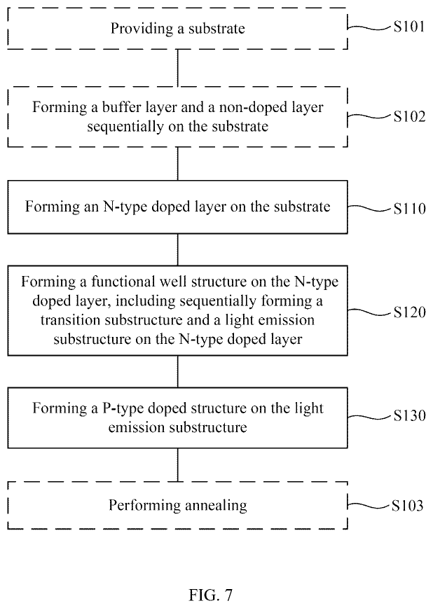

Referring to FIG. 7, FIG. 7 illustrates a schematic flowchart of a method for preparing an epitaxial wafer according to an embodiment of the present disclosure.

Referring to FIG. 1, FIG. 1 illustrates a schematic cross-sectional view of an epitaxial wafer formed by some embodiments of method for preparing the epitaxial wafer shown in FIG. 7.

The method includes the following steps: S110, forming an N-type doped layer 40 on a substrate; S120, forming a functional well structure 60 on the N-type doped layer 40, the step of forming the functional well structure 60 on the N-type doped layer 40 includes sequentially forming a transition substructure 61 and a light emitting substructure 62 on the N-type doped layer 40; S130, forming a P-type doped structure 70 on the light emitting substructure 62.

In some embodiments of the present disclosure, the method further includes the following steps: S101, providing a substrate 10 before performing step S110; S102, sequentially forming a buffer layer 20 and an undoped layer 30 on the substrate 10; and sequentially performing step S110, step S120 and step S130 to form the N-type doped layer 40, the functional well structure 60 and the P-type doped structure 70 on the undoped layer 30.

In some embodiments of the present disclosure, the step S110 of forming the N-type doped layer 40 on the substrate, the step S120 of forming the functional well structure 60, and the step S130 of forming the P-type doped structure 70 on a redundant barrier layer 622 are all performed by an epitaxial growth device. The step S110 of providing the substrate 10 includes: placing the substrate 10 in the epitaxial growth device after providing the substrate 10.

In some embodiments of the present disclosure, the step S102 of sequentially forming the buffer layer 20 and the undoped layer 30 on the substrate 10 includes: growing the buffer layer 20 on the substrate 10, and growing the undoped layer 30 on the buffer layer 20.

For example, in the step of growing the buffer layer 20 on the substrate 10, a temperature of the epitaxial growth device is in a range from 500° C. to 1000° C., and a pressure is in a range from 50 Torr to 500 Torr. A growth material source is introduced into the epitaxial growth device to grow the buffer layer 20 on the substrate 10.

In some embodiments, during the step of growing the buffer layer 20, at least two types of growth material sources are introduced into the epitaxial growth device to grow the buffer layer 20 having a single-layer structure or a multi-layer composite structure.

For example, in the step of growing the buffer layer 20 on the substrate 10, an Al source (such as trimethylaluminum) and an N source (such as ammonia) as growth material sources are introduced into the epitaxial growth device to grow the buffer layer 20 of AlN material. For example, in the step of growing the buffer layer 20 on the substrate 10, a Ga source (such as trimethylgallium or triethylgallium) and an N source (such as ammonia) as growth material sources are introduced into the epitaxial growth device to grow the buffer layer 20 of GaN material. For example, in the step of growing the buffer layer 20 on the substrate 10, an Al source (such as trimethylaluminum), a Ga source (such as trimethylgallium or triethylgallium) and an N source (such as ammonia) are introduced into the epitaxial growth device to grow the buffer layer 20 of AlGaN material. For example, in the step of growing the buffer layer 20 on the substrate 10, an Al source (such as trimethylaluminum), an In source (such as trimethylindium), a Ga source (such as trimethylgallium or triethylgallium) and an N source (such as ammonia) as growth material sources are introduced into the epitaxial growth device to grow the buffer layer 20 of AlInGaN material.

In the step of growing the undoped layer 30 on the buffer layer 20, the temperature of the epitaxial growth device is in a range from 1000° C. to 1200° C., and the pressure is in a range from 50 Torr to 500 Torr. The growth material source is introduced into the epitaxial growth device to grow the undoped layer 30 on the buffer layer 20.

In some embodiments, during the process of growing the undoped layer 30, at least two types of growth material sources are introduced into the epitaxial growth device to grow the undoped layer 30 having a single-layer structure or a multi-layer composite structure.

For example, in the step of growing the undoped layer 30 on the buffer layer 20, a Ga source (such as trimethylgallium) and an N source (such as ammonia) are introduced into the epitaxial growth device to grow the undoped layer 30 of GaN material. For example, in the step of growing the undoped layer 30 on the buffer layer 20, an Al source (such as trimethylaluminum), a Ga source (such as trimethylgallium) and an N source (such as ammonia) as growth material sources are introduced into the epitaxial growth device to grow the undoped layer 30 of AlGaN material. For example, in the step of growing the undoped layer 30 on the buffer layer 20, an Al source (such as trimethylaluminum), an In source (such as trimethylindium), a Ga source (such as trimethylgallium) and an N source (such as ammonia) as growth material sources are introduced into the epitaxial growth device to grow the undoped layer 30 of AlInGaN material.

In some embodiments of the present disclosure, in the step S110 of forming the N-type doped layer 40 on the substrate 10, the N-type doped layer 40 is grown on the undoped layer 30.

For example, the temperature of the epitaxial growth device is in a range from 1000° C. to 1100° C., and the pressure is in a range from 50 Torr to 300 Torr. The growth material sources and an N-type doped source are introduced into the epitaxial growth device. The N-type doped source may be at least one of a Si source and a Ge source.

In some embodiments, in the step of forming the N-type doped layer 40, at least two types of growth material sources are introduced into the epitaxial growth device to grow the N-type doped layer 40 having a single-layer structure or a multi-layer composite structure.

For example, in the step of forming the N-type doped layer 40, a Ga source (such as trimethylgallium), an N source (such as ammonia) and an N-type doped source are introduced into the epitaxial growth device to grow the N-type doped layer 40 of GaN material. For example, in the step of forming the N-type doped layer 40, an Al source (such as trimethylaluminum), a Ga source (such as trimethylgallium), an N source (such as ammonia) and an N-type doped source are introduced into the epitaxial growth device to grow the N-type doped layer 40 of AlGaN material. For example, in the step of forming the N-type doped layer 40, an Al source (such as trimethylaluminum), an In source (such as trimethylindium), a Ga source (such as trimethylgallium), an N source (such as ammonia) and an N-type doped source are introduced into the epitaxial growth device to grow the N-type doped layer 40 of AlInGaN material.

Still referring to FIG. 7, after forming the N-type doped layer 40, the step S120 of forming the functional well structure 60 is performed. The step S120 of forming the functional well structure 60 includes: forming the light emitting substructure 62 and the transition substructure 61.

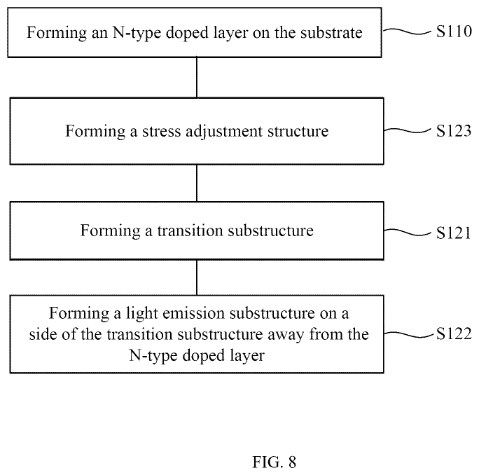

Referring to FIG. 8, FIG. 8 illustrates a schematic flowchart of steps for forming a functional well structure in the method for preparing an epitaxial wafer shown in FIG. 7 according to an embodiment of the present disclosure.

In some embodiments of the present disclosure, the step of forming the light emitting substructure 62 includes: forming a multi-period light emitting layer 621 on the transition substructure 61. In addition, in some embodiments, the step of forming the light emitting substructure further includes: forming a redundant barrier layer on the multi-period light emitting layer.

For example, the step of forming the light emitting substructure 62 and the transition substructure 61 includes the following steps: S121, forming the transition substructure 61; and S122, forming the light emitting substructure 62 on a side of the transition substructure 61 away from the N-type doped layer 40.

For example, the step of forming the light emitting substructure 62 and the transition substructure 61 includes: growing the transition substructure 61 on the N-type doped layer 40, and growing the light emitting substructure 62 on the transition substructure 61.

In some embodiments, the step S121 of forming the transition substructure 61 includes forming a transition stack layer. The step of forming the transition stack layer includes: forming a second barrier layer 61b, and forming a second well layer 61a. The second barrier layer 61b is disposed between the second well layer 61a of the same transition stack layer and the N-type doped layer 40. In the step S121 of forming the transition substructure 61, the step of forming the transition stack layer is performed for a plurality of times to form a plurality of transition stack layers stacked in a direction of a line connecting the N-type doped layer 40 and the P-type doped structure 70.

In some embodiments, the step of forming the transition stack layer includes: growing the second barrier layer 61b, and growing the second well layer 61a on the second barrier layer 61b. For example, in the step of forming the transition stack layer, the temperature of the epitaxial growth device is in a range from 750° C. to 900° C., and the pressure is in a range from 100 Torr to 500 Torr.

For example, in the step of growing the second barrier layer 41b on the N-type doped layer 40, an Al source (such as trimethylaluminum), a Ga source (such as triethylgallium), an N source (such as ammonia) and an N-type doped source are introduced into the epitaxial growth device to grow the second barrier layer 61b of N-type doped AlyGal-yN material, where 0<y≤0.2. The N-type doped source may be at least one of a Si source and a Ge source.

For example, in the step of growing the second barrier layer 61b on the N-type doped layer 40, a Ga source (such as triethylgallium), an N source (such as ammonia) and an N-type doped source are introduced into the epitaxial growth device to grow the second barrier layer 61b of N-type doped GaN material. The N-type doped source may be at least one of a Si source and a Ge source.

For example, in the step of growing the second well layer 61a on the second barrier layer 61b, an In source (such as trimethylindium), a Ga source (such as triethylgallium) and an N source (such as ammonia) are introduced into the epitaxial growth device to growth the second well layer 61a of InₓGa₁₋ₓN material on the second barrier layer 61b, where 0<x≤0.3.

In some embodiments of the present disclosure, the step of forming the second barrier layer 61b includes: providing an Al source (such as trimethylaluminum), a Ga source (such as triethylgallium) and an N source (such as ammonia) to form the second barrier layer 61b, and the second barrier layer 61b is an Al_{y}Ga_{1-y}N layer, where Oxy≤0.2. During performing the step of forming the transition stack layer for the plurality of times, an introducing amount of the Al source provided during forming the second barrier layer 61b in a latter step of forming the transition stack layer is greater than the introducing amount of the Al source provided during forming the second barrier layer 61b in a former step of forming the transition stack layer, so that a composition content of Al in the second barrier layer 61b on a side away from the N-type doped layer 40 is greater than the composition content of Al in the second barrier layer 61b on a side adjacent to the N-type doped layer 40.

It should be noted that during performing the step of forming the transition stack layer for the plurality of times, the latter step of forming the transition stack layer having a greater introducing amount of the Al source provided during forming the second barrier layer 61b and the former step of forming the transition stack layer having a smaller introducing amount of the Al source provided during forming the second barrier layer 61b may not be adjacent in the time domain.

In some embodiments, during performing the step of forming the transition stack layer for the plurality of times, the introducing amount of the Al source provided during forming the second barrier layer 61b in the step of forming the transition stack layer gradually increases by each time. During two adjacent steps of forming the transition stack layer, the introducing amount of the Al source provided during forming the second barrier layer in a latter step of forming the transition stack layer is greater than the introducing amount of the Al source provided during forming the second barrier layer in a former step of forming the transition stack layer. The introducing amount of the Al source provided during forming the second barrier layer in the same one step of forming the transition stack layer remains stable.

In some embodiments shown in FIG. 4, during performing the step of forming the transition stack layer for the plurality of times, the introducing amount of the Al source in the step of forming the second barrier layer 61b during performing the step of forming the transition stack layer for the second time to grow a second transition layer 612 is greater than the introducing amount of the Al source in the step of forming the second barrier layer 61b during performing the step of forming the transition stack layer for the first time to grow a first transition layer 611; the introducing amount of the Al source in the step of forming the second barrier layer 61b during performing the step of forming the transition stack layer for the third time to grow a third transition layer 613 is greater than the introducing amount of the Al source in the step of forming the second barrier layer 61b during performing the step of forming the transition stack layer for the second time to grow the second transition layer 612; . . . ; the introducing amount of the Al source in the step of forming the second barrier layer 61b during performing the step of forming the transition stack layer for the N2th time to grow an N2th transition layer 61N2 is greater than the introducing amount of the Al source in the step of forming the second barrier layer 61b during performing the step of forming the transition stack layer for the (N2-1)th time to grow a (N2-1)th transition layer 61N2-1.

However, the introducing amount of the Al source remains stable in the step of forming the second barrier layer 61b during performing the step of forming the transition stack layer for the first time to grow the first transition layer 611; the introducing amount of the Al source remains stable in the step of forming the second barrier layer 61b during performing the step of forming the transition stack layer for the second time to grow the second transition layer 612; the introducing amount of the Al source remains stable in the step of forming the second barrier layer 61b during performing the step of forming the transition stack layer for the third time to grow the third transition layer 613; . . . , the introducing amount of the Al source remains stable in the step of forming the second barrier layer 61b during performing the step of forming the transition stack layer for the (N2-1)th time to grow the (N2-1)th transition layer 61N2-1; and the introducing amount of the Al source remains stable in the step of forming the second barrier layer 61b during performing the step of forming the transition stack layer for the N2th time to grow the N2th transition layer 61N2 remains stable. For example, N2 is in a range from 3 to 5.

In some embodiments, during performing the step of forming the transition stack layer for the plurality of times, the introducing amount of the Al source in the step of forming the second barrier layer during performing the step of forming the transition stack layer gradually increases. For example, during performing the step of forming the transition stack layer for the plurality of times, in the step of forming the second barrier layer 61b during two adjacent steps of forming the transition stack layer, the introducing amount of the Al source in the step of forming the second barrier layer 61b in a latter step of forming the transition stack layer is greater than the introducing amount of the Al source in the step of forming the second barrier layer 61b in a former step of forming the transition stack layer. The introducing amount of the Al source during forming the second barrier layer 61b in the same one step of forming the transition stack layer also increases over time.

In some embodiments, during performing the step of forming the transition stack layer for the plurality of times, the introducing amount of the Al source in the step of forming the second barrier layer during performing the step of forming the transition stack layer for the second time to grow a second transition layer is greater than the introducing amount of the Al source in the step of forming the second barrier layer during performing the step of forming the transition stack layer for the first time to grow a first transition layer; the introducing amount of the Al source in the step of forming the second barrier layer during performing the step of forming the transition stack layer for the third time to grow a third transition layer is greater than the introducing amount of the Al source in the step of forming the second barrier layer during performing the step of forming the transition stack layer for the second time to grow the second transition layer; . . . ; the introducing amount of the Al source in the step of forming the second barrier layer during performing the step of forming the transition stack layer for the N2th time to grow an N2th transition layer is greater than the introducing amount of the Al source in the step of forming the second barrier layer during performing the step of forming the transition stack layer for the (N2-1)th time to grow a (N2-1)th transition layer.

Moreover, the introducing amount of the Al source increases over time in the step of forming the second barrier layer during performing the step of forming the transition stack layer for the first time to grow the first transition layer; the introducing amount of the Al source increases over time in the step of forming the second barrier layer during performing the step of forming the transition stack layer for the second time to grow the second transition layer; the introducing amount of the Al source increases over time in the step of forming the second barrier layer during performing the step of forming the transition stack layer for the third time to grow the third transition layer; . . . , the introducing amount of the Al source increases over time in the step of forming the second barrier layer during performing the step of forming the transition stack layer for the (N2-1)th time to grow the (N2-1)th transition layer; and the introducing amount of the Al source increases over time in the step of forming the second barrier layer during performing the step of forming the transition stack layer for the N2th time to grow the N2th transition layer.

Still referring to FIG. 8, after forming the transition substructure, the step S122 of form the light emitting substructure 62 is performed. For example, the light emitting substructure 62 is formed on the transition substructure 61. The step S122 of forming the light emitting substructure 62 includes: forming the multi-period light emitting layer 621 and the redundant barrier layer 622.

In some embodiments, the step S122 of forming the multi-period light emitting layer 621 and the redundant barrier layer 622 includes: forming the multi-period light emitting layer 621, and forming the redundant barrier layer 622 on a side of the multi-period light emitting layer 621 away from the N-type doped layer 40.

In some embodiments, the step of forming the multi-period light emitting layer 621 includes: forming a light emitting stack layer. The step of forming the light emitting stack layer includes: forming a first barrier layer 62b, and forming a first well layer 62a. The first barrier layer 61b is disposed between the first well layer 62a of the same light emitting stack layer and the N-type doped layer 40. In the step of forming the multi-period light emitting layer 621, the step of forming the light emitting stack layer is performed for a plurality of times to form a plurality of light emitting stack layers stacked in the direction of the line connecting the N-type doped layer 40 and the P-type doped structure 70.

In some embodiments, the step of forming the light emitting stack layer includes: growing the first barrier layer 62b, and growing the first well layer 62a on the first barrier layer 62b. For example, in the step of forming the light emitting stack layer, the temperature of the epitaxial growth device is in a range from 750° C. to 900° C., and the pressure is in a range from 50 Torr to 300 Torr. A Ga source (such as triethylgallium), an N source (such as ammonia) and an N-type doped source (such as at least one of a Si source and a Ge source) are introduced into the epitaxial growth device to grow the first barrier layer 62a of an N-type doped GaN material. Then, introducing the N-type doped source is stopped, and introducing the Ga source (such as triethylgallium) and the N source (such as ammonia) continues, and an In source (such as trimethylindium) is introduced into the epitaxial growth device. Then, the first well layer 62b of an In_{w}Ga_{1-w}N material is grown on the first barrier layer 62a, where 0.1≤w≤0.4.

After forming the multi-period light emitting layer 621, the redundant barrier layer 622 is grown on the multi-period light emitting layer 621. For example, in the step of forming the redundant barrier layer 622, the temperature of the epitaxial growth device is in a range from 750° C. to 900° C., and the pressure is in a range from 50 Torr to 300 Torr. A Ga source (such as triethylgallium) and an N source (such as ammonia) are introduced into the epitaxial growth device to grow the redundant barrier layer 622 of a GaN material on the multi-period light emitting layer 621.

In some embodiments, process conditions in the step of growing the redundant barrier layer 622 are the same as process conditions in the step of growing the first barrier layer 62b, and the formed redundant barrier layer 622 has the same property as the formed first barrier layer 62b. The redundant barrier layer 622 can serve as a potential barrier layer, and form a quantum well structure closest to the P-type doped structure 70 in the light emitting substructure 62 together with the first well layer 62a and the first barrier layer 62b in the N1th light emitting stack layer.

Still referring to FIG. 8, and referring to FIG. 6, in some embodiments of the present disclosure, the step of forming the functional well structure 60 includes: S123, forming a stress adjustment structure 50 after performing the step S110 of forming the N-type doped layer 40 on the substrate and before performing the step S121 of forming the transition substructure 61.

For example, the step of forming the functional well structure 60 includes: step S123, forming the stress adjustment structure 50 on the N-type doped layer 40 after performing the step S110 of forming the N-type doped layer 40 on the substrate and before performing the step S121 of forming the transition substructure 61.

In some embodiments of the present disclosure, the step of forming the stress adjustment structure 50 includes forming a stress adjustment stack layer. The step of forming the stress adjustment stack layer includes forming a third well layer 501, and forming a third barrier layer 502. The third barrier layer 502 is disposed between the third well layer 501 of the same stress adjustment stack layer and the N-type doped layer 40. In the step of forming the stress adjustment structure 50, the step of forming the stress adjustment stack layer is performed for a plurality of times to form a plurality of stress adjustment stack layers stacked in the direction of the line connecting the N-type doped layer 40 and the P-type doped structure 70.

In some embodiments, the step of forming the stress adjustment stack layer includes: growing the third barrier layer 502, and growing the third well layer 501 on the third barrier layer 503. For example, in the step of forming the stress adjustment stack layer, the temperature of the epitaxial growth device is in a range from 700° C. to 900° C., and the pressure is in a range from 100 Torr to 300 Torr.

For example, in the step of growing the third barrier layer 502 on the N-type doped layer 40, a Ga source (such as at least one of trimethylgallium and triethylgallium) and an N source (such as ammonia) are introduced into the epitaxial growth device to form the third barrier layer 501 of a GaN material on the N-type doped layer 40.

In the step of growing the third well layer 501 on the third barrier layer 503, after growing the third barrier layer 502 on the N-type doped layer 40, the Ga source and the N source continue to be introduced into the epitaxial growth device with a constant introducing amount, and an In source (such as trimethylindium) is introduced into the epitaxial growth device to grow the third well layer 502 of an In_{z}Ga₁₋₂N material on the third barrier layer 501, where 0<z≤0.1.

The Ga source introduced into the epitaxial growth device includes at least one of trimethylgallium and triethylgallium. After growing the third barrier layer 502 on the N-type doped layer 40, the Ga source continues to be introduced into the epitaxial growth device to grow the third well layer 502 of the In_{z}Ga₁₋₂N material. The Ga source introduced during growing the third well layer 501 on the third barrier layer 502 is the same as the Ga source introduced during growing the third barrier layer 502 on the N-type doped layer 40.

Still referring to FIG. 7, the method further includes: S130, forming the P-type doped structure 70 on the redundant barrier layer 622 after forming the functional well structure 60.

In some embodiments of the present disclosure, the step of forming the P-type doped structure 70 includes: forming a multi-period doped stack layer 72, and forming a P-type layer 71 on a side of the multi-period doped stack layer 72 away from the N-type doped layer 40. For example, the multi-period doped layer 72 is grown on the functional well structure 60.

In some embodiments, the step of forming the multi-period doped layer 72 includes forming a doped stack layer. The step of forming the doped stack layer includes: forming a ternary doped layer 72a, and forming a binary doped layer 72b. The ternary doped layer 72a is disposed between the binary doped layer 72b of the same doped stack layer and the functional well structure 60. In the step of forming the multi-period doped layer 72, the step of forming a doped stack layer is performed for a plurality of times to form a plurality of doped stack layers stacked in the direction of the line connecting the N-type doped layer 40 and the P-type doped structure 70.

As shown in FIG. 5, in the step of forming the multi-period doped layer 72, the step of forming the doped stack layer is performed for the first time to form a first doped stack layer 721, the step of forming the doped stack layer is performed for the second time to form a second doped stack layer 722, the step of forming the doped stack layer is performed for the third time to form a third doped stack layer 723, . . . , and the step of forming the doped stack layer is performed for the N3th to form a N3th doped stack layer 72N3.

In some embodiments, in the step of forming the multi-period doped layer 72, the step of forming the doped stack layer is performed for at least five times. In some embodiments shown in FIG. 5, N3 is in a range greater than or equal to 5.

In some embodiments, the step of forming the doped stack layer includes: providing a P-type doped source. During performing the step of forming the doped stack layer for the plurality of times, an introducing amount of the P-type doped source provided during the step of providing the P-type doped source in a former step of forming the doped stack layer is less than the introducing amount of the P-type doped source provided during the step of providing the P-type doped source in a latter step of forming the doped stack layer, so that a concentration of a P-type dopant in the multi-period doped layer 72 on the side away from the N-type doped layer 40 is greater than the concentration of the P-type dopant in the multi-period doped layer 72 on the side adjacent to the N-type doped layer 40.

It should be noted that during performing the step of forming the doped stack layer for the plurality of times, the former step of forming the doped stack layer having a smaller introducing amount of the P-type doped source during the step of providing the P-type doped source and the latter step of forming the doped stack layer having a greater introducing amount of the P-type doped source during the step of providing the P-type doped source may not be adjacent in the time domain.

In some embodiments, during performing the step of forming the doped stack layer for the plurality of times, the introducing amount of the P-type doped source provided during the step of forming the doped stack layer gradually increases by each time. In the process of forming the multi-period doped layer 72, during two adjacent steps of forming the doped stack layer, the introducing amount of the P-type doped source provided during the step of providing the P-type doped source in the latter step of forming the doped stack layer is greater than the introducing amount of the P-type doped source provided during the step of providing the P-type doped source in the former step of forming the doped stack layer.

As shown in FIG. 5, the introducing amount of the P-type doped source provided in the step of providing the P-type doped source during performing the step of forming the doped stack layer for the second time to grow the second doped stack layer 722 is greater than the introducing amount of the P-type doped source provided in the step of providing the P-type doped source during performing the step of forming the doped stack layer for the first time to grow the first doped stack layer 721; the introducing amount of the P-type doped source provided in the step of providing the P-type doped source during performing the step of forming the doped stack layer for the third time to grow the third doped stack layer 723 is greater than the introducing amount of the P-type doped source provided in the step of providing the P-type doped source during performing the step of forming the doped stack layer for the second time to grow the second doped stack layer 722; . . . ; the introducing amount of the P-type doped source provided in the step of providing the P-type doped source during performing the step of forming the doped stack layer for the N3th time to grow the N3th doped stack layer 72N3 is greater than the introducing amount of the P-type doped source provided in the step of providing the P-type doped source during performing the step of forming the doped stack layer for the (N-1)th time to grow the second doped stack layer 72(N-1). For example, N3 is in a range from 3 to 5.

In some embodiments, during each time of performing the step of forming the doped stack layer, the introducing amount of the P-type doped source remains stable. During each time of performing the step of forming the doped stack layer, the introducing amount of the P-type doped source during forming the ternary doped layer 72a remains stable and the introducing amount of the P-type doped source during forming the binary doped layer 72b remains stable. During each time of performing the step of forming the doped stack layer, the introducing amount of the P-type doped source during forming the ternary doped layer 72a and the introducing amount of the P-type doped source during forming the binary doped layer 72b are equal.

As shown in FIG. 5, during performing the step of forming the doped stack layer for the first time to grow the first doped stack layer 721, during performing the step of forming the doped stack layer for the second time to grow the second doped stack layer 722, during performing the step of forming the doped stack layer for the third time to grow the third doped stack layer 723, . . . , during performing the step of forming the doped stack layer for the N3th time to grow the N3th doped stack layer 72N3, the introducing amount of the P-type doped source during forming the ternary doped layer 72a and the introducing amount of the P-type doped source during forming the binary doped layer 72b remain stable respectively.

In other embodiments, during each time of performing the step of forming the doped stack layer, in the step of forming the ternary doped layer and in the step of forming the binary doped layer, the introducing amount of the P-type doped source provided in a latter step is greater than the introducing amount of the P-type doped source provided in a former step. For example, during each time of performing the step of forming the doped stack layer, the ternary doped layer is first grown on the functional well structure, and then the binary doped layer is grown on the ternary doped layer. During each time of performing the step of forming the doped stack layer, the introducing amount of the P-type doped source provided during forming the binary doped layer is greater than the introducing amount of the P-type doped source provided during forming the ternary doped layer. However, the introducing amount of the P-type doped source provided during forming the binary doped layer remains stable, and the introducing amount of the P-type doped source providing during forming the ternary doped layer remains stable.

For example, during performing the step of forming the doped stack layer for the first time to grow the first doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer remains stable, and the introducing amount of the P-type doped source provided during forming the ternary doped layer remains stable; during performing the step of forming the doped stack layer for the second time to grow the second doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer remains stable, and the introducing amount of the P-type doped source provided during forming the ternary doped layer remains stable; during performing the step of forming the doped stack layer for the third time to grow the third doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer remains stable, and the introducing amount of the P-type doped source provided during forming the ternary doped layer remains stable; . . . ; during performing the step of forming the doped stack layer for the N3th time to grow the N3th doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer remains stable, and the introducing amount of the P-type doped source provided during forming the ternary doped layer remains stable.

In other embodiments, during each time of performing the step of forming the doped stack layer, the introducing amount of the P-type doped source gradually increases. During each time of performing the step of forming the doped stack layer, the introducing amount of the P-type doped source provided during forming the binary doped layer is greater than the introducing amount of the P-type doped source during forming the ternary doped layer. Moreover, the introducing amount of the P-type doped source during forming the binary doped layer gradually increases, and the introducing amount of the P-type doped source during forming the ternary doped layer gradually increases.

For example, during performing the step of forming the doped stack layer for the first time to grow the first doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer gradually increases, and the introducing amount of the P-type doped source provided during forming the ternary doped layer gradually increases; during performing the step of forming the doped stack layer for the second time to grow the second doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer gradually increases, and the introducing amount of the P-type doped source provided during forming the ternary doped layer gradually increases; during performing the step of forming the doped stack layer for the third time to grow the third doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer gradually increases, and the introducing amount of the P-type doped source provided during forming the ternary doped layer gradually increases; . . . ; during performing the step of forming the doped stack layer for the N3th time to grow the N3th doped stack layer, the introducing amount of the P-type doped source provided during forming the binary doped layer is greater than the introducing amount of the P-type doped source provided during forming the ternary doped layer, while the introducing amount of the P-type doped source provided during forming the binary doped layer gradually increases, and the introducing amount of the P-type doped source provided during forming the ternary doped layer gradually increases.

In some embodiments, the step of forming the doped stack layer includes: growing the ternary doped layer 72a on the functional well structure, and growing the binary doped layer 72b on the ternary doped layer 72a. For example, in the step of forming the doped stack layer, the temperature of the epitaxial growth device is in a range from 720° C. to 950° C., and the pressure is in a range from 100 Torr to 300 Torr.

In some embodiments, in the step of forming the ternary doped layer 72a, an In source, a Ga source, an N source and a P-type doped source are provided to form the ternary doped layer 72a, and the ternary doped layer 72a is a P-type doped InGaN layer. In the step of forming the binary doped layer 72b, a Ga source, an N source and a P-type doped source are provided to form the binary doped layer 72b, and the binary doped layer 72b is a P-type doped GaN layer.

For example, in the step of growing the ternary doped layer 72a on the functional well structure, an In source (such as trimethylindium), a Ga source, an N source (such as ammonia) and a P-type doped source (such as at least one of a Mg source and a Zn source) are introduced into the epitaxial growth device to grow the ternary doped layer 72a of a P-type doped InGaN material.

For example, in the step of growing the binary doped layer 72b on the ternary doped layer 72a, the In source (such as trimethylindium) is stopped from being introduced into the epitaxial growth device, and the Ga source, the N source (such as ammonia) and the P-type doped source are continued to be introduced into the epitaxial growth device to grow the binary doped layer 72b of a P-type doped GaN material.

In some embodiments of the present disclosure, during performing the step of forming the doped stack layer for the plurality of times, the introducing amount of the Ga source provided during a former step of forming the doped stack layer is greater than the introducing amount of the Ga source provided during a latter step of forming the doped stack layer, and the introducing amount of the In source provided during forming the ternary doped layer 72a in the former step of forming the doped stack layer is smaller than introducing amount of the In source provided during forming the ternary doped layer 72a in the latter step of forming the doped stack layer, so that the component content of Ga in the multi-period doped layer on the side away from the N-type doped layer is lower than the component content of Ga in the multi-period doped layer adjacent to the N-type doped layer, and the component content of In in the InGaN layer in the multi-period doped layer on the side away from the N-type doped layer is higher than the component content of In in the InGaN layer in the multi-period doped layer adjacent to the N-type doped layer.

It should be noted that during performing the step of forming the doped stack layer for the plurality of times, the former step of forming the doped stack layer having a greater introducing amount of the Ga source and the latter step of forming the doped stack layer having a smaller introducing amount of the Ga source may not be adjacent in the time domain. and the former step of forming the doped stack layer having a smaller introducing amount of the In source during forming the ternary doped layer 72a and the latter step of forming the doped stack layer having a greater introducing amount of the In source during forming the ternary doped layer 72a may not be adjacent in the time domain.

In some embodiments, during performing the step of forming the doped stack layer for the plurality of times, the introducing amount of the Ga source provided during the step of forming the doped stack layer gradually decreases by each time, and during performing the step of forming the doped stack layer for the plurality of times, the introducing amount of the In source provided during the step of forming the ternary doped layer 72a gradually increases by each time. During forming the multi-period doped layer 72, during two adjacent steps of forming the doped stack layer, the introducing amount of the Ga source provided during the latter step of forming the doped stack layer is smaller than the introducing amount of the Ga source provided during the former step of forming the doped stack layer, and the introducing amount of the In source provided during forming the ternary doped layer 72a during the latter step of forming the doped stack layer is greater than the introducing amount of the In source provided during forming the ternary doped layer 72a during the former step of forming the doped stack layer.

As shown in FIG. 5, the introducing amount of the Ga source provided during performing the step of forming the doped stack layer for the second time to grow the second doped stack layer 722 is smaller than the introducing amount of the Ga source provided during performing the step of forming the doped stack layer for the first time to grow the first doped stack layer 721; the introducing amount of the Ga source provided during performing the step of forming the doped stack layer for the third time to grow the third doped stack layer 723 is smaller than the introducing amount of the Ga source provided during performing the step of forming the doped stack layer for the second time to grow the second doped stack layer 722; . . . , the introducing amount of the Ga source provided during performing the step of forming the doped stack layer for the N3th time to grow the second doped stack layer 72N3 is smaller than the introducing amount of the Ga source provided during performing the step of forming the doped stack layer for the N3-1 time to grow the first doped stack layer 72N3-1. For example, N3 is in a range greater than or equal to 5.

In addition, the introducing amount of the In source provided during forming the ternary doped layer 72a during performing the step of forming the doped stack layer for the second time to grow the second doped stack layer 722 is greater than the introducing amount of the In source provided during forming the ternary doped layer 72a during performing the step of forming the doped stack layer for the first time to grow the first doped stack layer 721; the introducing amount of the In source provided during forming the ternary doped layer 72a during performing the step of forming the doped stack layer for the third time to grow the third doped stack layer 723 is greater than the introducing amount of the In source provided during forming the ternary doped layer 72a during performing the step of forming the doped stack layer for the second time to grow the second doped stack layer 721; . . . ; the introducing amount of the In source provided during forming the ternary doped layer 72a during performing the step of forming the doped stack layer for the N3th time to grow the N3th doped stack layer 722 is greater than the introducing amount of the In source provided during forming the ternary doped layer 72a during performing the step of forming the doped stack layer for the (N3-1)th time to grow the first doped stack layer 72N3-1. For example, N3 is in a range greater than or equal to 5.

In some embodiments, during each time of performing the step of forming the doped stack layer, the introducing amount of the Ga source remains stable; and during each time of performing the step of forming the doped stack layer, the introducing amount of the In source provided during forming the ternary doped layer 72a remains stable. During each time of performing the step of forming the doped stack layer, the introducing amount of the Ga source provided during forming the ternary doped layer 72a remains stable, and the introducing amount of the Ga source provided during forming the binary doped layer 72b remains stable. During each time of performing the step of forming the doped stack layer, the introducing amount of the Ga source provided during forming the ternary doped layer 72a and the introducing amount of the Ga source provided during forming the binary doped layer 72b are equal. During each time of performing the step of forming the doped stack layer, the introducing amount of the In source provided during forming the ternary doped layer 72a remains stable.

As shown in FIG. 5, during performing the step of forming the doped stack layer for the first time to grow the first doped stack layer 721, during performing the step of forming the doped stack layer for the second time to grow the second doped stack layer 722, during performing the step of forming the doped stack layer for the third time to grow the third doped stack layer 723, . . . , during performing the step of forming the doped stack layer for the N3th time to grow the N3th doped stack layer 72N3, the introducing amount of the Ga source provided during forming the ternary doped layer 72a remains stable, and the introducing amount of the Ga source provided during the binary doped layer 72b remains stable.

During performing the step of forming the doped stack layer for the first time to grow the first doped stack layer 721, during performing the step of forming the doped stack layer for the second time to grow the second doped stack layer 722, during performing the step of forming the doped stack layer for the third time to grow the third doped stack layer 723, . . . , during performing the step of forming the doped stack layer for the N3th time to grow the N3th doped stack layer 72N3, the introducing amount of the In source provided during forming the ternary doped layer 72a remains stable.

In other embodiments, during each time of performing the step of forming the doped stack layer, the introducing amount of the Ga source provided during forming the binary doped layer is smaller than the introducing amount of the Ga source provided during forming the ternary doped layer. For example, during each time of performing the step of forming the doped stack layer, the ternary doped layer is first grown on the functional well structure, and then the binary doped layer is grown on the ternary doped layer. During each time of performing the step of forming the doped stack layer, the introducing amount of the Ga source provided during forming the binary doped layer is smaller than the introducing amount of the Ga source provided during forming the ternary doped layer, while the introducing amount of the Ga source provided during forming the binary doped layer remains stable, and the introducing amount of the Ga source provided during the forming the ternary doped layer remains stable.

For example, during performing the step of forming the doped stack layer for the first time to grow the first doped stack layer, the introducing amount of the Ga source provided during forming the binary doped layer is smaller than the introducing amount of the Ga source provided during forming the ternary doped layer, while the introducing amount of the Ga source provided during forming the binary doped layer remains stable, and the introducing amount of the Ga source provided during forming the ternary doped layer remains stable; during performing the step of forming the doped stack layer for the second time to grow the second doped stack layer, the introducing amount of the Ga source provided during forming the binary doped layer is smaller than the introducing amount of the Ga source provided during forming the ternary doped layer, while the introducing amount of the Ga source provided during forming the binary doped layer remains stable, and the introducing amount of the Ga source provided during forming the ternary doped layer remains stable; during performing the step of forming the doped stack layer for the third time to grow the third doped stack layer, the introducing amount of the Ga source provided during forming the binary doped layer is smaller than the introducing amount of the Ga source provided during forming the ternary doped layer, while the introducing amount of the Ga source provided during forming the binary doped layer remains stable, and the introducing amount of the Ga source provided during forming the ternary doped layer remains stable; . . . ; during performing the step of forming the doped stack layer for the N3th time to grow the N3th doped stack layer, the introducing amount of the Ga source provided during forming the binary doped layer is smaller than the introducing amount of the Ga source provided during forming the ternary doped layer, while the introducing amount of the Ga source provided during forming the binary doped layer remains stable, and the introducing amount of the Ga source provided during forming the ternary doped layer remains stable.

In other embodiments, during each time of performing the step of forming the doped stack layer, the introducing amount of the Ga source gradually decreases, and during each time of performing the step of forming the doped stack layer, the introducing amount of the In source provided during forming the ternary doped layer gradually increases. During each time of performing the step of forming the doped stack layer, the introducing amount of the Ga source provided during forming the binary doped layer is smaller than the introducing amount of the Ga source provided during forming the ternary doped layer, while the introducing amount of the Ga source provided during forming the binary doped layer gradually decreases, and the introducing amount of the Ga source provided during forming the ternary doped layer gradually decreases.

For example, during performing the step of forming the doped stack layer for the first time to grow the first doped stack layer, the introducing amount of the Ga source provided during forming the binary doped layer is smaller than the introducing amount of the Ga source provided during forming the ternary doped layer, while the introducing amount of the Ga source provided during forming the binary doped layer gradually decreases, and the introducing amount of the Ga source provided during forming the ternary doped layer gradually decreases; during performing the step of forming the doped stack layer for the second time to grow the second doped stack layer, the introducing amount of the Ga source provided during forming the binary doped layer is smaller than the introducing amount of the Ga source provided during forming the ternary doped layer, while the introducing amount of the Ga source provided during forming the binary doped layer gradually decreases, and the introducing amount of the Ga source provided during forming the ternary doped layer gradually decreases; during performing the step of forming the doped stack layer for the third time to grow the third doped stack layer, the introducing amount of the Ga source provided during forming the binary doped layer is smaller than the introducing amount of the Ga source provided during forming the ternary doped layer, while the introducing amount of the Ga source provided during forming the binary doped layer gradually decreases, and the introducing amount of the Ga source provided during forming the ternary doped layer gradually decreases; . . . ; during performing the step of forming the doped stack layer for the N3th time to grow the N3th doped stack layer, the introducing amount of the Ga source provided during forming the binary doped layer is smaller than the introducing amount of the Ga source provided during forming the ternary doped layer, while the introducing amount of the Ga source provided during forming the binary doped layer gradually decreases, and the introducing amount of the Ga source provided during forming the ternary doped layer gradually decreases.

The introducing amount of the In source provided during forming the ternary doped layer during performing the step of forming the doped stack layer for the second time to grow the second doped stack layer is greater than the introducing amount of the In source provided during forming the ternary doped layer during performing the step of forming the doped stack layer for the first time to grow the first doped stack layer; the introducing amount of the In source provided during forming the ternary doped layer during performing the step of forming the doped stack layer for the third time to grow the third doped stack layer is greater than the introducing amount of the In source provided during forming the ternary doped layer during performing the step of forming the doped stack layer for the second time to grow the second doped stack layer; . . . ; the introducing amount of the In source provided during forming the ternary doped layer during performing the step of forming the doped stack layer for the N3th time to grow the N3th doped stack layer is greater than the introducing amount of the In source provided during forming the ternary doped layer during performing the step of forming the doped stack layer for the (N3-1)th time to grow the first doped stack layer. Moreover, during performing the step of forming the doped stack layer for the first time to grow the first doped stack layer, during performing the step of forming the doped stack layer for the second time to grow the second doped stack layer, during performing the step of forming the doped stack layer for the third time to grow the third doped stack layer, . . . , during performing the step of forming the doped stack layer for the N3th time to grow the N3th doped stack layer 72N3, the introducing amount of the In source provided during forming the ternary doped layer remains stable. For example, N3 is in a range greater than or equal to 5.

It should be noted that in the step of forming the multi-period doped layer 72, the Ga source may include at least one of trimethylgallium and triethylgallium. The Ga source introduced into the epitaxial growth device may include at least one of trimethylgallium and triethylgallium.

The step of forming the P-type doped structure 70 further includes: forming the P-type layer 71 on the multi-period doped layer 72 after forming the multi-period doped layer 72.

For example, during the step of growing the P-type layer 71, the temperature of the epitaxial growth device is in a range from 720° C. to 950° C., and the pressure is in a range from 100 Torr to 300 Torr. An In source (such as trimethylindium), a Ga source, an N source (such as ammonia) and the P-type doped source (such as at least one of a Mg source and a Zn source) are introduced into the epitaxial growth device to grow the P-type layer 71 of a P-type doped InGaN material on the multi-period doped layer 72. The Ga source may include at least one of trimethylgallium and triethylgallium.

In some embodiments, during performing the step of forming the doped stack layer for the plurality of times, the step of forming the doped stack layer are performed for at least five times.

Still referring to FIG. 7, the method further includes: S103, performing annealing after forming the N-type doped layer 40, the functional well structure 60 and the P-type doped structure 70. For example, annealing is performed after forming the P-type doped structure.

In some embodiments, during the step of performing annealing, an annealing temperature is in a range from 500° C. to 780° C.

In some embodiments, the step S110 of forming the N-type doped layer 40 on the substrate, the step S120 of forming the functional well structure 60 and the step S130 of forming the P-type doped structure 70 are all performed by an epitaxial growth device. In the step of annealing, the temperature of the epitaxial growth equipment is set to the annealing temperature for performing annealing. In the step of annealing, the temperature of the epitaxial growth device is in a range from 500° C. to 780° C. for performing annealing.

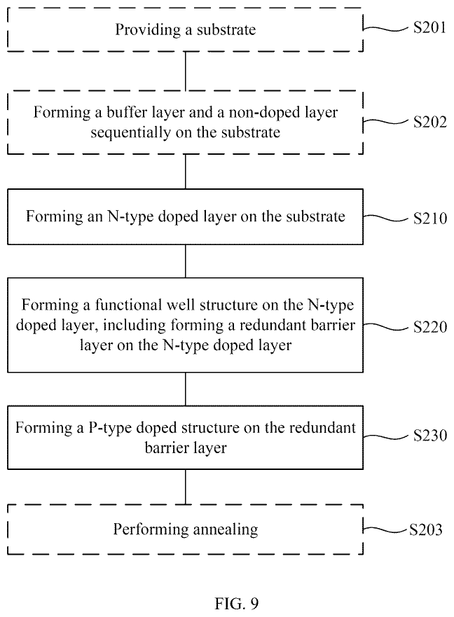

Referring to FIG. 9, FIG. 9 illustrates a schematic flowchart of a method for preparing an epitaxial wafer according to an embodiment of the present disclosure.

Referring to FIG. 1, FIG. 1 illustrates a schematic cross-sectional view of an epitaxial wafer formed by the method for preparing the epitaxial wafer shown in FIG. 7 according to some embodiments.

The method for preparing the epitaxial wafer includes the following steps: S210, forming an N-type doped layer 40 on a substrate; S220, forming a functional well structure 60 on the N-type doped layer 40, the step of forming the functional well structure 60 on the N-type doped layer 40 includes forming a redundant barrier layer 622 on the N-type doped layer 40; S230, forming a P-type doped structure 70 on the redundant barrier layer 622.

In some embodiments of the present disclosure, as shown in FIG. 2, the method for preparing the epitaxial wafer further includes the following steps: S201, providing the substrate before the step S210 of forming the N-type doped layer 40 on the substrate 10; S202, sequentially forming a buffer layer 20 and an undoped layer 30 on the substrate 10 after providing the substrate; and then sequentially performing the step S210, the step S220 and the step S230 to sequentially form the N-type doped layer 40, the functional well structure 60 and the P-type doped structure 70 on the undoped layer 30.

The step S201 of providing the substrate and the step S202 of sequentially forming the buffer layer 20 and the undoped layer 30 on the substrate 10 are similar or the same as the embodiments of the method for preparing the epitaxial wafer described above. The specific technical solutions for the step S201 of providing the substrate and the step S202 of sequentially forming the buffer layer 20 and the undoped layer 30 on the substrate 10 can refer to the embodiments of the method for preparing the epitaxial wafer described above.

In some embodiments of the present disclosure, the step of forming the functional well structure 60 on the N-type doped layer 40 further includes: forming a multi-period light emitting layer 621 on a side of the N-type doped layer 40 away from the substrate 10 before the step of forming the redundant barrier layer 622.

The step of forming the multi-period light emitting layer 621 on the side of the N-type doped layer 40 away from the substrate 10 is similar or the same as the embodiments of the method for preparing the epitaxial wafer described above. The specific technical solution for the step of forming the multi-period light emitting layer 621 on the side of the N-type doped layer 40 away from the substrate 10 can refer to the embodiments of the method for preparing the epitaxial wafer described above.

In some embodiments, the step of forming the functional well structure 60 further includes: forming a stress adjustment structure 50 on the side of the N-type doped layer 40 away from the substrate 10 before forming the multi-period light emitting layer 621.

The step of forming the stress adjustment structure 50 on the side of the N-type doped layer 40 away from the substrate 10 is similar or the same as the embodiments of the method for preparing the epitaxial wafer described above. The specific technical solution for the step of forming the stress adjustment structure 50 on the side of the N-type doped layer 40 away from the substrate 10 can refer to the method for preparing the epitaxial wafer described above.

In some embodiments of the present disclosure, the step of forming the P-type doped structure 70 includes: forming a multi-period doped layer 72 on a side of the redundant barrier layer 622 away from the N-type doped layer 40; and forming a P-type layer 71 on a side of the multi-period doped layer 72 away from the N-type doped layer 40.

The step of forming the multi-period doped layer 72 on the side of the redundant barrier layer 622 away from the N-type doped layer 40 and the step of forming the P-type layer 71 on the side of the multi-period doped layer 72 away from the N-type doped layer 40 are similar or the same as the embodiments of the method for preparing the epitaxial wafer described above. The specific technical solutions for the step of forming the multi-period doped layer 72 on the side of the redundant barrier layer 622 away from the N-type doped layer 40 and the step of forming the P-type layer 71 on the side of the multi-period doped layer 72 away from the N-type doped layer 40 can refer to the embodiments of the method for preparing the epitaxial wafer described above.

In some embodiments of the present disclosure, the method for preparing the epitaxial wafer further includes: S203, performing annealing after the step of forming the P-type doped structure 70.

The step S203 of performing annealing is similar or the same as the embodiments of the method for preparing the epitaxial wafer described above. The specific technical solution for step S203 of performing annealing can refer to the embodiments of the method for preparing the epitaxial wafer described above.

In the epitaxial wafer of the present disclosure, the functional well structure disposed between the N-type doped layer and the P-type doped structure includes a light emitting substructure and a transition substructure disposed between the light emitting substructure and the N-type doped layer. In the light emitting substructure, the multi-period light emitting layer is a multiple quantum well structure, and a barrier layer in the multiple quantum well structure and the redundant barrier layer have a weak blocking effect on holes, which can increase a migration distance of holes, thereby increasing the number of light emitting quantum wells and improving the light emitting efficiency of the epitaxial wafer. The transition substructure is disposed between the light emitting substructure and the N-type doped layer, thus an electron concentration of the light emitting layer can be effectively controlled without an N-type current diffusion layer between the N-type doped layer and the light emitting substructure, which can improve a balance between electrons and holes in the light emitting layer, thereby effectively improving the light emitting efficiency of the epitaxial wafer. Moreover, the electron concentration in the light emitting layer can be controlled through the transition substructure without an electron blocking layer between the P-type doped layer and the light emitting substructure, which can effectively increase a migration distance of holes and effectively improve the light emitting efficiency of the epitaxial wafer.

According to some embodiments, the P-type doped structure includes a P-type layer and a multi-period doped layer. The multi-period doped layer is disposed between the P-type layer and the functional well structure. The multi-period doped layer includes a plurality of doped stack layers, and each of the plurality of doped stack layers includes a ternary doped layer and a binary doped layer. The ternary doped layer is disposed between the binary doped layer of a same doped stack layer and the functional well structure. The multi-period doped layer can increase effective hole concentration, improve hole injection efficiency, enhance a balance of electrons and holes in the light emitting substructure, lower an annealing temperature for subsequent annealing process, and effectively reduce an impact of the annealing process on potential wells in the functional well structure.

The above-mentioned epitaxial wafer can be used in a micro display panel.

The above-mentioned display panel has a very small volume with a length and a width ranging from 500 μm to 50000 μm. The light emitting area of the above-mentioned display panel is very small, such as 1 mm×1 mm, 2.64 mm×2.02 mm, 3 mm×5 mm, etc. The light emitting area of the above-mentioned display panel includes a plurality of micro LED pixels arranged in an array, such as a 320×240, 640×480, 1600×1200, 1920×1080 or 2560×1440-pixel array. The dimension of each micro LED pixel is in the range of 100 nm to 100 μm. In some embodiments, the dimension of each micro LED pixel is in the range of 150 nm to 15 μm. In some embodiments, the dimension of each micro LED pixel can be smaller than 10 μm.

A drive backplane is arranged on a back surface of the micro LED pixel array, and the drive backplane is electrically connected with the micro LEDs in the micro LED pixel array. The drive backplane can acquire image data and other signals from outside to control corresponding micro LEDs to emit light or not. The drive backplane may be a TFT (Thin Film Transistor) substrate or an IC (Integrated Circuit) substrate.

In some embodiments, the drive backplane of the above-mentioned display panel integrates a frame buffer, a column driving circuit and a row drive circuit. The frame buffer includes a first pixel storage area, and the micro LED pixel array includes a second pixel storage area. A complete frame of pixel grayscale data from the outside can first enter the first pixel storage area of the frame buffer. The column drive circuit can load the pixel grayscale data in the first pixel storage area of the frame buffer into the second pixel storage area of the micro LED pixel array. The row drive circuit can scan the pixel grayscale data in the second pixel storage area and generate a pulse modulation signal to display different grayscale levels. When driving a plurality of micro LED pixels in the micro LED pixel array, single pixel independent driving mode or a plurality of pixel units independent driving mode can be adopted, and the specific driving mode should not limit the present disclosure.

It should be noted that the application of the above-mentioned epitaxial wafer in the micro display panel should not constitute a limitation on the application of the present disclosure.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

What is claimed is:

1. An epitaxial wafer, comprising an N-type doped layer, a functional well structure and a P-type doped structure sequentially arranged in a stacked manner;
wherein the functional well structure comprises a light emitting substructure, and the light emitting substructure comprises a redundant barrier layer, wherein the redundant barrier layer is disposed between the N-type doped layer and the P-type doped structure.

2. The epitaxial wafer according to claim 1, wherein the light emitting substructure further comprises a multi-period light emitting layer disposed between the N-type doped layer and the redundant barrier layer.

3. The epitaxial wafer according to claim 2, wherein the multi-period light emitting layer comprises a plurality of light emitting stack layers, wherein each of the plurality of light emitting stack layers comprises a first barrier layer and a first well layer, and the first barrier layer is disposed between the first well layer of a same light emitting stack layer and the N-type doped layer.

4. The epitaxial wafer according to claim 1, wherein the P-type doped structure comprises a P-type layer and a multi-period doped layer disposed between the P-type layer and the functional well structure.

5. The epitaxial wafer according to claim 4, wherein the multi-period doped layer comprises a plurality of doped stack layers, and each of the plurality of doped stack layers comprises a ternary doped layer and a binary doped layer, wherein the ternary doped layer is disposed between the binary doped layer of a same doped stack layer and the functional well structure.

6. The epitaxial wafer according to claim 1, wherein the functional well structure further comprises a stress adjustment structure disposed between the N-type doped layer and the light emitting substructure.

7. The epitaxial wafer according to claim 6, wherein the stress adjustment structure comprises a plurality of stress adjustment stack layers, and each of the plurality of stress adjustment stack layers comprises a third well layer and a third barrier layer, wherein the third barrier layer is disposed between the third well layer of a same adjustment stack layer and the N-type doped layer.

8. The epitaxial wafer according to claim 1, further comprising an undoped layer, a buffer layer and a substrate;
wherein the substrate is disposed on a side of the N-type doped layer away from the P-type doped structure;
the buffer layer is disposed between the substrate and the N-type doped layer; and
the undoped layer is disposed between the buffer layer and the N-type doped layer.

9. The epitaxial wafer according to claim 1, wherein the functional well structure further comprises a transition substructure disposed between the light emitting substructure and the N-type doped layer.

10. The epitaxial wafer according to claim 9, wherein the transition substructure comprises a plurality of transition stack layers, and each of the plurality of transition stack layers comprises a second barrier layer and a second well layer, wherein the second barrier layer is disposed between the second well layer of a same transition stack layer and the N-type doped layer.

11. A display device, comprising an epitaxial wafer according to claim 1.

12. A method for preparing an epitaxial wafer according to claim 1, comprising:
forming the N-type doped layer on a substrate;
forming the functional well structure on the N-type doped layer, wherein the step of forming the functional well structure on the N-type doped layer comprises: forming the redundant barrier layer on the N-type doped layer; and
forming the P-type doped structure on the redundant barrier layer.

13. The method according to claim 12, wherein the step of forming the functional well structure on the N-type doped layer further comprises: forming a multi-period light emitting layer on a side of the N-type doped layer away from the substrate before the step of forming the redundant barrier layer.

14. The method according to claim 13, wherein the step of forming the functional well structure further comprises: forming a stress adjustment structure on the side of the N-type doped layer away from the substrate before forming the multi-period light emitting layer.

15. The method according to claim 12, wherein the step of forming the P-type doped structure comprises: forming a multi-period doped layer on a side of the redundant barrier layer away from the N-type doped layer, and forming a P-type layer on a side of the multi-period doped layer away from the N-type doped layer.

16. The method according to claim 15, wherein the step of forming the multi-period doped layer comprises: forming a doped stack layer, and the step of forming the doped stack layer comprises: forming a ternary doped layer, and forming a binary doped layer on a side of the ternary doped layer away from the substrate; and
wherein the step of forming the multi-period doped layer comprises performing the step of forming the doped stack layer for a plurality of times to form a plurality of doped stack layers in a direction of a line connecting the N-type doped layer and the P-type doped structure.

17. The method according to claim 12, further comprising: forming a buffer layer and an undoped layer sequentially on the substrate before the step of forming the N-type doped layer.

18. The method according to claim 12, further comprising: performing annealing after the step of forming the P-type doped structure.

19. The method according to claim 12, wherein the step of forming the functional well structure on the N-type doped layer further comprises sequentially forming a transition substructure and a light emitting substructure on the N-type doped layer, wherein the light emitting substructure comprises the redundant barrier layer.

20. The method according to claim 19, wherein the step of forming the transition substructure comprises: forming a transition stack layer on the N-type doped layer, and the step of forming the transition stack layer on the N-type doped layer comprises: forming a second barrier layer, and forming a second well layer on a side of the second barrier layer away from the N-type doped layer; and
wherein the step of forming the transition substructure comprises performing the step of forming the transition stack layer on the N-type doped layer for a plurality of times to form a plurality of transition stack layers in a direction of a line connecting the N-type doped layer and the P-type doped structure.
